(19) United States
(12) Patent Application Publication
(10) Pub. No.: US 2023/0197509 A1
(43) Pub. Date: Jun. 22, 2023

(54) WET FUNCTIONALIZATION OF DIELECTRIC SURFACES

(71) Applicant: Lam Research Corporation, Fremont, CA (US)

(72) Inventors: Lee J. Brogan, Newberg, OR (US); Matthew Martin Huie, Tigard, OR (US); Yi Hua Liu, Sherwood, OR (US); Jonathan David Reid, Sherwood, OR (US)

(21) Appl. No.: 17/926,093

(22) PCT Filed: May 20, 2021
(86) PCT No.: PCT/US2021/033329

§ 371 Date: Nov. 17, 2022

Related U.S. Application Data
(60) Provisional application No. 62/704,692, filed on May 22, 2020.

(51) Int. Cl. H01L 21/768; C23C 16/06; C23C 16/455; C23C 16/02; C23C 18/31; C23C 18/16

(52) U.S. Cl. CPC H01L 21/76843; C23C 16/06; C23C 16/0272; C23C 16/45525; C23C 18/31; C23C 18/165; H01L 21/76826; C23F 17/00

(57) ABSTRACT

Various embodiments relate to methods, apparatus, and systems for forming an interconnect structure, or a portion thereof. The method may include contacting the substrate with a functionalization bath comprising a first solvent and a functionalization reactant to form a modified first material, and then depositing a second material on the modified first material through electroless plating, electroplating, chemical vapor deposition, or atomic layer deposition. The first material may be a dielectric material, a barrier layer, or a liner, and the second material may be a barrier layer or a barrier layer precursor, a liner, a seed layer, or a conductive metal that forms the interconnect of the interconnect structure, according to various embodiments.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

As semiconductor device dimensions continue to shrink, fabrication of such devices becomes increasingly difficult. In many cases, existing processes are not capable of forming desired materials and structures within acceptable tolerances.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, apparatus, and systems for forming an interconnect structure, or a portion thereof, on a semiconductor substrate. In various embodiments, wet processing methods are used to functionalize an exposed surface to promote improved deposition of a subsequent layer.

In one aspect of the disclosed embodiments, a method of forming an interconnect structure, or a portion thereof, on a substrate is provided, the method including: (a) receiving the substrate in a wet processing chamber, the substrate including dielectric material with recessed features formed in the dielectric material, where the interconnect structure is to be formed in the recessed features, where a first material is exposed within the recessed features; (b) contacting the substrate with a functionalization bath including a first solvent and a functionalization reactant to form a modified first material on a surface of the first material, (i) where the modified first material includes the first material modified by the functionalization reactant, and (ii) where the functionalization reactant includes (1) a binding functional group that binds the functionalization reactant to the first material, and (2) an active functional group that promotes deposition of a second material on the modified first material, where the binding functional group and the active functional group may be the same or different; and (c) depositing the second material on the modified first material, (i) where the second material is deposited through electroless plating, electroplating, chemical vapor deposition, or atomic layer deposition, and (ii) where one of the following conditions is satisfied: (1) the first material is the dielectric material and the second material is a barrier layer or a barrier layer precursor, (2) the first material is the barrier layer and the second material is a liner, (3) the first material is the barrier layer and the second material is a conductive metal that forms the interconnect of the interconnect structure, (4) the first material is the barrier layer and the second material is a seed layer, (5) the first material is the liner and the second material is the seed layer, or (6) the first material is the liner and the second material is the conductive metal that forms the interconnect of the interconnect structure.

In some embodiments, the first material may be the dielectric material and the second material may be the barrier layer or the barrier layer precursor. In some embodiments, the first material may be the barrier layer and the second material may be the liner. In some embodiments, the first material may be the barrier layer and the second material may be the conductive metal that forms the interconnect of the interconnect structure. In some embodiments, the first material may be the liner and the second material may be the conductive metal that forms the interconnect of the interconnect structure. In some embodiments, the first material may be the barrier layer and the second material may be the seed layer. In some embodiments, the first material may be the liner and the second material may be the seed layer.

In some implementations, the active functional group may include a reducing functional group. In some such embodiments, the reducing functional group may include a material selected from the group consisting of: a borohydride, a borane, an aldehyde, an acid, a hypophosphite, hydrazine, a glycol, a reductive metal ion, a substituted form of any of these materials, and combinations thereof. In some cases the reducing functional group includes the borohydride In some cases the reducing functional group includes the borane. In some cases the reducing functional group includes the aldehyde. In some such cases the aldehyde is formaldehyde. In some cases the reducing functional group includes the acid. The acid may be selected from the group consisting of glyoxylic acid, pyruvic acid, ascorbic acid, and combinations thereof. In some cases the reducing functional group includes the hypophosphite. In some cases the reducing functional group comprises the hydrazine. In some cases the reducing functional group comprises the glycol. In some cases the glycol is ethylene glycol. In some cases the reducing functional group comprises the reductive metal ion. In some cases the reductive metal ion is selected from the group consisting of Fe(II), Cr(II), Ti(III), V(II), and combinations thereof. In some implementations, the active functional group may include a catalyzing functional group. In some such embodiments, the catalyzing functional group may include nanoparticles of a metal and/or nanoparticles of a metal oxide.

In certain embodiments, the active functional group may include a decomplexing functional group. In some such embodiments, the decomplexing functional group may include a material selected from the group consisting of: a hydroxide, an alcohol, an ester, an ether, a carboxylic acid, and combinations thereof. In some cases, the active functional group may include an adhesive functional group. In some such embodiments, the adhesive functional group may include a material selected from the group consisting of: a hydroxide, an alcohol, a carboxylic acid, a metal oxide, and combinations thereof. In some cases, the adhesive functional group includes the hydroxide. In some cases, the adhesive functional group includes the alcohol. In some cases, the adhesive functional group includes the carboxylic acid. In some cases, the adhesive functional group includes the metal oxide.

In some embodiments, the binding functional group may include a physisorbing functional group. In some such embodiments, the physisorbing functional group may include a material selected from the group consisting of: a phosphonate, a carboxylate, an amine, an alkyne, an alkene, catechol, a catechol derivative, and combinations thereof. In some embodiments, the physisorbing functional group includes the phosphonate. In some embodiments, the physisorbing functional group includes the carboxylate. In some embodiments, the physisorbing functional group includes the amine. In some embodiments, the physisorbing functional group includes the alkyne. In some embodiments, the physisorbing functional group includes the alkene. In some embodiments, the physisorbing functional group includes the In some embodiments, the binding functional group includes a chemisorbing functional group. In some such embodiments, the chemisorbing functional group may include a material selected from the group consisting of: a hydroxide, a silane, an ester, a silazane, a silyl-acetamide, a silyl-imidazole, and combinations thereof. In some cases, the chemisorbing functional group includes the hydroxide. In some cases, the chemisorbing functional group includes silicon. In some cases, the chemisorbing functional group includes the silane. In some such cases, the silane is a halosilane. In some cases, the silane is an alkoxy-silane. In some cases, the silane is an acyloxy-silane. In some cases, the silane is an allylsilane. In some cases, the silane is an arylsilane. In some cases, the silane is a methylsilane. In some cases, the silane is a vinylsilane. In some cases, the chemisorbing functional group includes the ester. In some cases, the ester is a N-hydroxysuccinimide ester. In some cases the chemisorbing functional group includes the silazane. In some cases, the silazane is a disilazane or a trisilazane. In some cases, the chemisorbing functional group includes the silyl-acetamide. In some cases, the chemisorbing functional group includes the silyl-imidazole.

The functionalization bath may include additional species. In some embodiments, the functionalization bath further may include a pH adjustment species including a base or an acid, In some cases, the pH adjustment species includes the base. In some cases, the base of the pH adjustment species may include a material selected from the group consisting of: triethylamine, tetramethylammonium hydroxide, ammonium hydroxide, and combinations thereof. In some cases, the pH adjustment species includes the acid. In some cases, the acid of the pH adjustment species may include a material selected from the group consisting of sulfuric acid, hydrochloric acid, nitric acid, phosphoric acid, and combinations thereof.

The second material may be deposited using various deposition techniques. In some embodiments, the second material may be deposited through electroless plating. In some embodiments, the second material may be deposited through electroplating. In some embodiments, the second material may be deposited through chemical vapor deposition. In some embodiments, the second material may be deposited through atomic layer deposition. In some implementations, the second material may be deposited in a deposition bath including a solvent and a metal mass source, where the second material includes a metal in the metal mass source. In certain embodiments, the second material may be deposited in a vapor deposition chamber using a metal mass source, where the second material includes a metal in the metal mass source.

In various embodiments, the metal mass source may include a metal salt. For example, the metal salt may include a material selected from the group consisting of: a metal halide, a metal sulfite, a metal sulfate, a metal hydroxide, a metal nitrate, a metal phosphite, a metal phosphate, and combinations thereof. In some cases, the metal salt includes the metal halide. In some cases, the metal salt includes the metal sulfite. In some cases, the metal salt includes the metal sulfate. In some cases, the metal salt includes the metal hydroxide. In some cases, the metal salt includes the metal nitrate. In some cases, the metal salt includes the metal phosphite. In some cases, the metal salt includes the metal phosphate. In some embodiments, the metal mass source may include a ligated organometallic precursor. In some such cases, the ligated organometallic precursor may include a material selected from the group consisting of: a metal halide, a metal alkyl, a metal cyclopentadienyl, a metal hexane derivative, a cyclic organometallic compound, a metal alkoxide, a metal beta-diketonate, a metal amide, a metal imide, a metal amidinate, a metal phosphine, a metal vinyl silane, a metal carboxyl, a metal amidinato, a metal pyrrolyl derivative, a metal bidentate, a metal polycyclic ligand, and combinations thereof. In some cases, the ligated organometallic precursor includes the metal halide. In some cases, the ligated organometallic precursor includes the metal alkyl. In some cases, the ligated organometallic precursor includes the metal cyclopentadienyl. In some cases, the ligated organometallic precursor includes the metal hexane derivative. In some cases, the ligated organometallic precursor includes the cyclic organometallic compound. In some cases, the ligated organometallic precursor includes the metal alkoxide. In some cases, the ligated organometallic precursor includes the metal beta-diketonate. In some cases, the ligated organometallic precursor includes the metal amide. In some cases, the ligated organometallic precursor includes the metal imide. In some cases, the ligated organometallic precursor includes the metal amidinate. In some cases, the ligated organometallic precursor includes the metal phophine. In some cases, the ligated organometallic precursor includes the metal vinyl silane. In some cases, the ligated organometallic precursor includes the metal carboxyl. In some cases, the ligated organometallic precursor includes the metal amidinato. In some cases, the ligated organometallic precursor includes the metal pyrrolyl derivative. In some cases, the ligated organometallic precursor includes the metal bidentate. In some cases, the ligated organometallic precursor includes the metal polycyclic ligand.

In some embodiments, the second material may be the barrier layer precursor, and the method may further include exposing the substrate to an anneal process that converts the barrier layer precursor to the barrier layer. In some such cases, the anneal process may include heating the substrate to a temperature between about 150-400° C. In these or other cases, the anneal process may include exposing the substrate to a hydrogen plasma. In certain implementations, the barrier layer may include a metal silicate that forms from a reaction between the dielectric material and a metal in the barrier layer precursor.

In various embodiments, the second material may include a metal selected from the group consisting of: tantalum, titanium, zinc, tin, magnesium, manganese, indium, aluminum, cobalt, iridium, ruthenium, copper, molybdenum, palladium, tungsten, and combinations thereof. In some cases, the metal in the second material is selected from the group consisting of magnesium, titanium tantalum, and combinations thereof. In some cases, the metal in the second material is selected from the group consisting of manganese, cobalt, copper, zinc, and combinations thereof. In some cases, the metal in the second material is selected from the group consisting of molybdenum, ruthenium, palladium, tungsten, iridium, and combinations thereof. In some cases, the metal in the second material is selected from the group consisting of aluminum, indium, tin, and combinations thereof. In some cases, the metal in the second material includes tantalum. In some cases, the metal in the second material includes titanium. In some cases, the metal in the second material includes zinc. In some cases, the metal in the second material includes tin. In some cases, the metal in the second material includes magnesium. In some cases, the metal in the second material includes manganese. In some cases, the metal in the second material includes indium. In some cases, the metal in the second material includes aluminum. In some cases, the metal in the second material includes cobalt. In some cases, the metal in the second material includes iridium. In some cases, the metal in the second material includes ruthenium. In some cases, the metal in the second material includes copper. In some cases, the metal in the second material includes molybdenum. In some cases, the metal in the second material includes palladium. In some cases, the metal in the second material includes tungsten. In some embodiments, the first material may be the dielectric material and the second material may be the barrier layer or the barrier layer precursor, where the second material includes a metal oxide. In various cases, the metal oxide may include a material selected from the group consisting of: zinc oxide, tin oxide, manganese oxide, magnesium oxide, molybdenum nitride, and combinations thereof.

In certain implementations, the first solvent of the functionalization bath may include water. In other implementations, the first solvent of the functionalization bath may be non-polar.

In some embodiments, the first material may be the dielectric material and the second material may be the barrier layer precursor, the first solvent and the functionalization reactant may each be water, the binding functional group of the functionalization reactant may be hydroxyl, which may bind to the dielectric material, the active functional group of the functionalization reactant may also be hydroxyl, which may promote deposition of the barrier layer precursor, the barrier layer precursor may be deposited through chemical vapor deposition or atomic layer deposition, and the method may further include exposing the substrate to an anneal process to convert the barrier layer precursor to the barrier layer.

In certain embodiments, the first material may be the dielectric material and the second material may be the barrier layer precursor, the first solvent may include water, the binding functional group of the functionalization reactant may include a physisorbing functional group that binds to the dielectric material, the active functional group of the functionalization reactant may include a reducing group that promotes deposition of the barrier layer precursor, the barrier layer precursor may be wholly or partially deposited through electroless plating in a deposition bath including a second solvent and a metal salt, and the reducing functional group may reduce the metal of the metal salt to cause deposition of the barrier layer precursor. In some implementations, the physisorbing functional group may include an alcohol. The alcohol may include catechol or a catechol derivative, the reducing functional group may include borohydride, the second solvent may include water, and the metal salt may include a metal sulfate. In some implementations, the method may further include contacting the substrate with the functionalization bath a second time, then contacting the substrate with the deposition bath a second time, to cause further deposition of the barrier layer precursor. In some implementations, the method may further include adding a reducing species to the deposition bath to cause further deposition of the barrier layer precursor after a portion of the barrier layer precursor is deposited. In some implementations, the method may further include depositing additional barrier layer precursor through chemical vapor deposition or atomic layer deposition after an initial portion of the barrier layer precursor is deposited through electroless plating. In some implementations, the method may further include exposing the substrate to an anneal to convert the barrier layer precursor to the barrier layer.

In some embodiments, the first material may be the dielectric material and the second material may be the barrier layer precursor, the first solvent of the functionalization bath may be non-polar, the binding functional group of the functionalization reactant may include a chemisorbing group that binds to the dielectric material, and the active functional group of the functionalization reactant may include a reducing functional group that promotes deposition of the barrier layer precursor. In some implementations, the first solvent may include toluene, the chemisorbing group may include an alkoxysilane, and the reducing functional group may include a glycol. The glycol may be ethylene glycol. In some implementations, the substrate may be maintained at a temperature between about 60-80° C. while contacting the functionalization bath. In some implementations, the barrier layer precursor may be deposited through electroless plating in a deposition bath including a second solvent and a metal salt, and the reducing functional group of the functionalization reactant may act to reduce a metal in the metal salt to cause deposition of the barrier layer precursor In some implementations, the barrier layer precursor may be deposited through chemical vapor deposition or atomic layer deposition using a metal mass source, and the reducing functional group of the functionalization reactant may act to reduce a metal in the metal mass source to cause deposition of the barrier layer precursor. In some implementations, the method may further include exposing the substrate to an anneal process to convert the barrier layer precursor to the barrier layer.

In certain embodiments, the first material may be the dielectric material and the second material may be the barrier layer precursor, the active functional group of the functionalization reactant may include a catalyzing functional group, and the barrier layer precursor may be deposited using electroless plating in a deposition bath including a second solvent, a metal salt, and a reducing species. In some implementations, the first solvent of the functionalization bath may include water, the binding group of the functionalization reactant may include catechol or a catechol derivative, the catalyzing functional group of the functionalization reactant may include cobalt nanoparticles, the second solvent of the deposition bath may include water, the metal salt may include metal sulfate, and the reducing species may include borohydride. In some implementations, the method may further include maintaining a concentration of dissolved oxygen in the deposition bath within a target range during deposition of the barrier layer precursor. In some implementations, the method may further include exposing the substrate to an anneal process to convert the barrier layer precursor to the barrier layer.

In certain embodiments, the first material may be the dielectric material and the second material may be the barrier layer precursor, the active functional group of the functionalization reactant may include a decomplexing functional group, the barrier layer precursor may be partially or wholly deposited through electroless plating in a deposition bath including a second solvent and a ligated organometallic precursor, and the decomplexing functional group may interact with the ligated organometallic precursor to release a metal from the ligated organometallic precursor to cause deposition of the barrier layer precursor. In some implementations, the first solvent of the functionalization bath may include water, the decomplexing functional group of the functionalization reactant may include carboxylic acid, and the ligated organometallic precursor may include an acetate-ligated metal. In some implementations, the method may further include contacting the substrate with the functionalization bath a second time, then contacting the substrate with the deposition bath a second time, to cause further deposition of the barrier layer precursor. In some implementations, the method may further include depositing additional barrier layer precursor through chemical vapor deposition or atomic layer deposition after an initial portion of the barrier layer precursor is deposited through electroless plating. In some implementations, the method may further include exposing the substrate to an anneal to convert the barrier layer precursor to the barrier layer. In some implementations, the first solvent and the functionalization reactant of the functionalization bath may each be water, the binding functional group of the functionalization reactant may be hydroxyl, which may bind to the dielectric material, the active functional group of the functionalization reactant may also be hydroxyl, which may promote deposition of the barrier layer precursor, the barrier layer precursor may be deposited using chemical vapor deposition with a ligated organometallic precursor, and the hydroxyl of the functionalization reactant may interact with the ligated organometallic precursor to release a metal in the ligated organometallic precursor to cause deposition of the barrier layer precursor. In some implementations, the ligated organometallic precursor may include diethyl zinc. In some embodiments, the method may further include exposing the substrate to an anneal process that converts the barrier layer precursor to the barrier layer, the barrier layer including zinc silicate. In some embodiments, the method may further include exposing the substrate to hydrogen plasma to volatilize excess zinc, then depositing a copper seed layer, then depositing the conductive metal that forms the interconnect of the interconnect structure through electroplating.

In another aspect of the disclosed embodiments, a system for forming an interconnect structure, or a portion thereof, on a substrate, is provided, the system including: (a) a first wet processing chamber; (b) an optional second wet processing chamber; (c) an optional vacuum chamber; and (d) a controller configured to cause any of the methods described herein.

In another aspect of the disclosed embodiments, a system for forming an interconnect structure, or a portion thereof, on a substrate, is provided, the system including: (a) a first wet processing chamber; (b) an optional second wet processing chamber; (c) an optional vacuum chamber; and (d) a controller configured to cause; (i) receiving the substrate in the wet processing chamber, the substrate including dielectric material with recessed features formed in the dielectric material, where the interconnect structure is to be formed in the recessed features, where a first material is exposed within the recessed features; (ii) contacting the substrate with a functionalization bath including a first solvent and a functionalization reactant to form a modified first material on a surface of the first material, (1) where the modified first material includes the first material modified by the functionalization reactant, and (2) where the functionalization reactant includes (A) a binding functional group that binds the functionalization reactant to the first material, and (B) an active functional group that promotes deposition of a second material on the modified first material, where the binding functional group and the active functional group may be the same or different; and (iii) depositing the second material on the modified first material while the substrate is either in the first wet processing chamber, the optional second wet processing chamber, or the optional vacuum chamber, (1) where the second material is deposited through electroless plating, electroplating, chemical vapor deposition, or atomic layer deposition, and (2) where one of the following conditions is satisfied: (a) the first material is the dielectric material and the second material is a barrier layer or a barrier layer precursor, (b) the first material is the barrier layer and the second material is a liner, (c) the first material is the barrier layer and the second material is a conductive metal that forms the interconnect of the interconnect structure, (d) the first material is the barrier layer and the second material is a seed layer, (e) the first material is the liner and the second material is the seed layer, or (f) the first material is the liner and the second material is the conductive metal that forms the interconnect of the interconnect structure.

These and other aspects are described further below with reference to the drawings.

### BRIEF DESCRIPTION OF THE DRAWINGS

FIG. 1 illustrates an interconnect structure according to various embodiments.

FIG. 2 is a flowchart describing a method of functionalizing a layer of material and depositing an additional material thereon.

FIG. 3 is a flowchart describing a particular embodiment of the method of FIG. 2, where the layer of material that is modified is a layer of dielectric material and the additional material that is deposited on the dielectric material is a barrier layer or a barrier layer precursor.

FIG. 4 depicts a wet processing vessel according to various embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

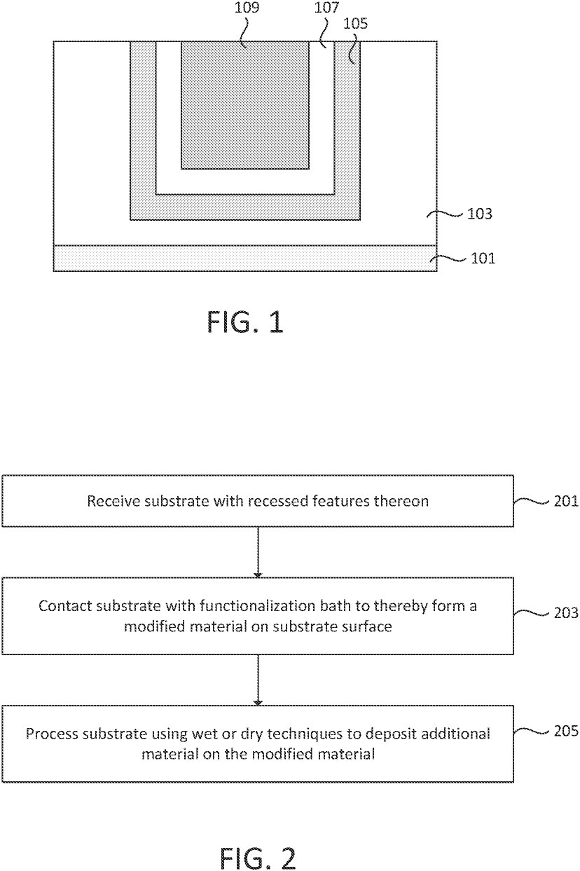

One of the processes involved in back-end-of-line (BEOL) semiconductor fabrication is the formation of interconnects that electrically connect two or more circuit elements together. FIG. 1 illustrates an example of a substrate 101 with an interconnect structure formed thereon. The substrate 101 has dielectric material 103 thereon, which has been etched to form a recessed feature. Within the recessed feature, a barrier layer 105 is present on the dielectric material 103. An optional liner 107 may be present on the barrier layer 105. Conducting metal 109 is present on the optional liner 107 or on the barrier layer 105. The conducting metal 109 functions as an interconnect.

Generally speaking, there is a widely used industry standard for forming the interconnect structure shown in FIG. 1 (e.g., for metallizing BEOL interconnects). This industry standard utilizes a specific stack of materials that are manufactured by processes that have been proven to result in low defects both immediately after manufacture and over time. However, as device dimensions continue to shrink, the industry standard stack is beginning to occupy too much of the available interconnect volume, resulting in line resistances which are too high. However, due to various constraints, it can be difficult to modify the industry standard stack.

For example, the dielectric material 103 should have low permittivity and an associated low dielectric constant (κ) to minimize RC delay of the circuit. As used herein, a material with a dielectric constant of about 3.7 or less is considered a low-k material. The dielectric material 103 should also be readily etched in order to form the relevant circuitry, and should have sufficient mechanical strength to resist pattern collapse after etching.

The barrier layer 105 is provided to minimize or eliminate diffusion of conductive metal 109 into dielectric material 103. Without a barrier layer 105, the conducting metal 109 will typically diffuse into the dielectric material 103, which results in an increase of the dielectric constant and eventually short-circuiting of the interconnects. The barrier layer 105 should therefore be effective in preventing diffusion of the conductor metal 109. Further, it should have good adhesion to the dielectric material 103 and to the optional liner 107 or to the conductive metal 109 itself. It is desirable for the barrier layer 105 to be as thin and conductive as possible. The process used to form the barrier layer 105 should exhibit good nucleation on the dielectric material 103, should produce a continuous film with few or no defects that would compromise the barrier layer’s ability to prevent metal diffusion, and should produce nearly conformal step coverage to prevent pinching off narrow features. For commercial processing, few barrier materials have been able to satisfy these constraints. In some cases, stacks of tantalum/tantalum nitride are used as a barrier layer 105. In some limited cases, stacks of titanium/titanium nitride are used as a barrier layer 105. Physical vapor deposition or reactive sputtering are commonly used to deposit these materials to thereby form the barrier layer 105.

The optional liner 107 may be provided between the barrier layer 105 and the conductive metal 109. When present, the liner 107 may mitigate a shortcoming of the barrier layer 105. For instance, if the barrier layer 105 does not have sufficient adhesion to the conductive metal 109, the liner 107 may be provided to ensure adequate adhesion between relevant layers (e.g., between the barrier layer 105 and the liner 107, and between the liner 107 and the conductive metal 109). In some cases, a cobalt liner is used, for example between a tantalum nitride barrier layer and copper.

A seed layer (not shown in FIG. 1) may be provided on the barrier layer 105 or on the optional liner 107 in some cases. The seed layer is conductive and may be made of the same material as the bulk conductive metal 109. The seed layer enables subsequent deposition of the bulk conductor metal 109. In some cases, another layer in the stack (e.g., barrier layer 105 or optional liner 107) is sufficiently conductive such that no additional seed layer is needed. In cases where a seed layer is deposited, it is typically formed through physical vapor deposition.

The conductive metal 109 acts as an interconnect to electrically connect different devices on the substrate 101. The conductive metal 109 is typically formed through electrodeposition, which provides good filling properties at relatively low cost. The conductive metal 109 typically fills the volume of the recessed feature that is not occupied by the other layers mentioned above.

Each of the stack components described above presents several constraints regarding material properties, interfacial properties, etc. As such, a change to any individual component within the stack can cause significant issues with regard to the rest of the stack. Further, many materials that are available could only be deposited through a single deposition technique, for example because alternative deposition methods have shown unsatisfactory results with respect to nucleation, purity, morphology, cost, or detectivity.

In various embodiments herein, one or more of the layers described in FIG. 1 may be modified in a wet functionalization process to facilitate subsequent processing. Many types of modifications are available. Generally, the modification involves functionalizing an exposed surface of the substrate to enable or substantially improve deposition of a subsequent layer, which may be deposited through wet or dry techniques.

Much of the description herein relates to embodiments where a wet functionalization step is performed on the dielectric material 103, to thereby facilitate subsequent deposition of the barrier layer 105 or a material that is further processed to form the barrier layer 105. However, it is understood that the techniques described herein may be applied to any one or more of the layers/interfaces shown in FIG. 1. For instance, in one embodiment the techniques described herein are used to functionalize an upper surface of the barrier layer 105, to thereby facilitate subsequent deposition of the liner 107. In another embodiment, the techniques described herein are used to functionalize an upper surface of the barrier layer 105, to thereby facilitate subsequent deposition of the seed layer. In another embodiment, the techniques described herein are used to functionalize an upper surface of the barrier layer 105, to thereby facilitate subsequent deposition of the conductive metal 109. In another embodiment, the techniques described herein are used to functionalize an upper surface of the liner 107, to thereby facilitate subsequent deposition of the seed layer. In another embodiment, the techniques described herein are used to functionalize an upper surface of the liner 107, to thereby facilitate subsequent deposition of the conductive metal 109. In another embodiment, the techniques described herein are repeated to functionalize two or more of the layers/interfaces shown in FIG. 1.

One advantage of the wet functionalization process is that it allows for deposition of a wider variety of materials, for example for the barrier layer 105, the liner 107, and the seed layer, that were previously not available. In other words, the wet treatment process enables formation of interconnect stacks that have useful properties and materials, but which were previously not manufacturable due to the lack of a suitable processing method. The techniques herein represent a substantial improvement in manufacturing capabilities.

In certain embodiments, dielectric material 103 may be a silicon-containing dielectric material such as silicon, silicon oxide, silicon nitride, silicon carbide, or trielemental combinations including Si and a combination of C, N, or O. The dielectric material 103 may be doped with a material such as carbon, nitrogen, etc. In these or other embodiments, the barrier layer 105 may be a metal and/or metal nitride. The barrier layer 105 may be a metal, metal nitride, metal oxide, metal carbide, and/or metal silicate, and may include a metal selected from the group consisting of: tantalum, titanium, zinc, tin, magnesium, manganese, indium, aluminum, cobalt, iridium, ruthenium, copper, molybdenum, palladium, tungsten, and combinations thereof. The material selected for the barrier layer 105 should provide a good diffusion barrier to prevent the conductive metal 109 from diffusing into the dielectric material 103. As such, it should include a metal that is different from the metal in the conductive metal 109 or otherwise bind the conductive metal in such a state that it remains immobile. Particular example materials for the barrier layer 105 include, but are not limited to, zinc oxide, tin oxide, manganese oxide, magnesium oxide, and tungsten carbonitride, in addition to the materials listed above.

In these or other embodiments, the liner 107 (if present) may be or include a metal selected from the group consisting of: tantalum, titanium, zinc, tin, magnesium, manganese, indium, aluminum, cobalt, iridium, ruthenium, copper, molybdenum, palladium, tungsten, and combinations thereof. In these or other embodiments, the seed layer (if present) may be or include a metal selected from the group consisting of: aluminum, copper, cobalt, iridium, ruthenium, molybdenum, palladium, tungsten, and combinations thereof. In these or other embodiments, the conductive metal 109 may be a metal selected from the group consisting of: aluminum, copper, cobalt, iridium, ruthenium, molybdenum, palladium, tungsten, and combinations thereof.

Another advantage of the wet functionalization step is that it can be used to enable deposition methods that were not previously available in the context of BEOL interconnect formation. For example, as mentioned above, barrier layer materials are typically deposited through physical vapor deposition or reactive sputtering techniques. Chemical vapor deposition (CVD), atomic layer deposition (ALD), and electroless plating were previously not available for this step because such processes show very poor nucleation on dielectric materials, and the adhesion between the dielectric material and the deposited barrier layer material (or barrier layer precursor) is poor. However, in various embodiments herein, a wet functionalization step may be performed on the dielectric material to thereby functionalize the upper surface of the dielectric material with functional groups that enhance nucleation and adhesion during a subsequent CVD, ALD, electroplating, or electroless plating step. Such enhancements can overcome the poor nucleation and adhesion that would otherwise occur without the wet functionalization step. As such, the techniques described herein enable the use of deposition processes/process flows that were not previously available.

In the past, wet processes have been avoided in the context of BEOL interconnect fabrication, except for electrodeposition of the bulk conductive metal (e.g., conductive metal 109 in FIG. 1). Even substrate rinsing has been avoided in the BEOL interconnect context to ensure that liquid water does not contact the substrate and the materials thereon. Wet processes have been avoided because they were seen as causing damage to the dielectric material and/or other materials present on the substrate. However, the inventors have discovered that certain surface modifications that can occur during wet processing can be advantageous, rather than harmful, when practiced according to the techniques described herein. These findings were unexpected.

### I. Functionalization Bath

During the wet functionalization step, the substrate is exposed to a functionalization bath. The functionalization bath is liquid phase and includes a solvent and at least one chemical that reacts with the layer being modified (e.g., the layer of dielectric material, the barrier layer, or the liner). The chemical that reacts with the layer being modified may be referred to as the functionalization reactant. In many cases, the solvent and the functionalization reactant are separate species, and the functionalization reactant is dissolved in the solvent. In some cases, the functionalization reactant may be the solvent itself (e.g., in one example the solvent is water, which functionalizes a relevant material with hydroxyl groups). The functionalization reactant may include a single species, or it may include a combination of species. Many classes of functionalization reactants are available and are considered to be within the scope of the disclosed embodiments. In some cases, the functionalization bath may further include a species to adjust the pH of the functionalization bath.

### A. Solvent

The solvent in the functionalization bath is selected to properly solvate the functionalization reactant and any other chemistry that may be present in the functionalization bath. Further, the solvent is selected to properly wet the material being modified (e.g., the layer of dielectric material, the barrier layer, or the liner).

In various embodiments, the solvent in the functionalization bath may include water, toluene, hexane, an alcohol (e.g., methanol, ethanol, etc.), acetone, carbon tetrachloride, chloroform, glycerin, acetonitrile, dimethyl sulfoxide, a derivative of these materials, and combinations thereof.

Where the solvent includes an alcohol, the alcohol may have a formula of X-C(R)ₙ(OH)-Y, where:

n is 1;

each X and Y can be independently selected from hydrogen, —[C(R¹)₂]ₘ—C(R²)₃, or OH, wherein each R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10; and each R independently is selected from hydrogen, hydroxyl, aliphatic, haloaliphatic, haloheteroaliphatic, heteroaliphatic, aromatic, aliphatic-aromatic, heteroaliphatic-aromatic, or any combinations thereof.

In some embodiments, each R, R¹ and R² independently is selected from alkyl, alkenyl, alkynyl, heteroalkyl, heteroalkenyl, heteroalkynyl, haloalkyl, haloalkenyl, haloalkynyl, haloheteroalkyl, halohteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl heterocyclyl, heteroalkyl-heteroaryl, heteroalkenyl-heteroaiyl, heteroalkynyl-heteroaryl, or any combinations thereof. In particular disclosed embodiments, the alcohol may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In other embodiments, when at least one of X or Y = —[C(R¹)₂]ₘ—C(R²)₃ or R is a hydrogen and m is 1, the alcohol can be a C₃ alcohol. For instance, if at least one R¹ and one R² is absent, then the C₃ alcohol can be a C₃ alkenol (e.g., allyl alcohol). In another instance, R and one R² together can form a ring(such as, cycloaliphatic), then the C₃ alcohol can be a cyclopropanol or 2-cyclopropenol.

In yet other embodiments, when at least one of X or Y = —[C(R¹)₂]ₘ—C(R²)₃ of R is a hydrogen and m is 2, the alcohol can be a C₄ alcohol. For instance, if at least one R¹ and one R² is absent, then the C₄ alcohol can be a C₄ alkenol (e.g., 2-buten-1-ol or 3-buten-1-ol). In another instance, R and one R² together can form a ring (such as, cycloaliphatic), then the C₄ alcohol can be a C₄-cyclic alcohol (e.g., cyclobutanol or a cyclopropylmethanol). In yet another instance, if both X and Y are not OH, then the C₄ alcohol can be a C₄-branched alcohol (e.g., 2-butanol, isobutanol, or tert-butanol).

In some instances, when X = OH and Y = —[C(R¹)₂]ₘ—C(R²)₃, the alcohol can be a diol. In other instances, when at least one X or Y= -[C(R¹)₂]ₘ-C(R²)₃ and at least one R¹ = OH or one R² = OH, or when R= OH, the alcohol can be a diol. Example diols include, but are not limited to, 1,4-butane diol, propylene-1,3-diol, and the like.

In other instances, when X = Y = OH, the alcohol can be a triol. In yet other instances, when X = R = OH, the alcohol can be a triol. In some instances, when at least one of X or Y is —[C(R¹)₂]ₘ—C(R²)₃ and one R¹ and at least one R² is OH, the alcohol can be triol. In other instances, when R = OH and X = —[C(R¹)₂]ₘ—C(R²)₃ and one R¹ and at least one R² is OH, the alcohol can be triol. Example triols include, but are not limited to, glycerol of glycerine derivatives thereof.

In particular embodiments, when R = cycloheteroaliphatic, heterocyclyl, heteroaryl, alkyl-heterocyclyl, alkenyl-heterocyclyl, alkynyl-heterocyclyl, heteroalkyl-heterocyclyl, heteroalkenyl-heterocyclyl, or heteroalkynyl-heterocyclyl, the alcohol can be a heterocyclyl alcohol (e.g., an optionally substituted heterocyclyl substituted with or more hydroxyls, such as furfuryl alcohol). In other embodiments, when at least one of X or Y is —[C(R¹)₂]ₘ—C(R—²)₃ and one R¹ and at least one R² is cycloheteroaliphatic, heterocyclyl, heteroaryl, alkyl-heterocyclyl, alkenyl-heterocyclyl, alkynyl-heterocyclyl, heteroalkyl-heterocyclyl, heteroalkenyl-heterocyclyl, or heteroalkynyl-heterocyclyl, the alcohol can be a heterocyclyl alcohol.

In various embodiments, the alcohol may have between 1-10 carbon atoms. The alcohol may be a primary alcohol, a secondary alcohol, or a tertiary alcohol. In some cases, the alcohol may be selected from the group consisting of: methanol, ethanol, 1-propanol, 2-propatiol, 1-butanol, 2-butanol, t-butanol, 1-pentanol, 1-hexanol, 1-heptanol, 1-octanol, 1-nonanol, 1-decanol, and combinations thereof.

In cases where the functionalization reactant is polar, the solvent may also be polar. As used herein, a solvent or functionalization reactant that has a relative polarity of about 0.2 or greater is considered to be polar. The relative polarity is calculated as a ratio between the polarity of the material of interest and the polarity of pure water. One example of a polar solvent is water (relative polarity of 1). In cases where the functionalization reactant is nonpolar, or where the functionalization reactant or substrate are reactive to water, the solvent may be nonpolar. Example nonpolar solvents include toluene (relative polarity of 0.099) and hexane (relative polarity of 0.009). Generally, polar solvents tend to have a high dipole moment and a high dielectric constant.

### B. Functionalization Reactant

The functionalization reactant in the functionalization bath is provided to bind to the material being modified and to facilitate deposition in a subsequent processing step. As such, the functionalization reactant may include a binding functional group and an active functional group.

### 1. Binding Functional Group

The binding functional group enables the functionalization reactant to bind or otherwise adhere to the surface being modified. In one example where the dielectric material is being modified, the binding functional group allows the functionalization reactant to adhere directly onto the dielectric material. Similarly, in cases where the barrier layer or liner are being modified, the binding functional group allows the functionalization reactant to adhere directly onto the barrier layer or liner, respectively. The adhesion may occur through various mechanisms including, e.g., physisorption and/or chemisorption.

One advantage of using a binding functional group is that it allows for targeted/preferential modification of and deposition on desired surfaces. For instance, in one embodiment where a substrate includes a first exposed material and a second exposed material, the binding functional group can be selected to preferentially bind to the first exposed material compared to the second exposed material. As a result, the first exposed material will be preferentially modified compared to the second exposed material. Because the modification facilitates deposition, a subsequent deposition step can then proceed to preferentially deposit on the modified first exposed material, as compared to the second exposed material.

### A. Physisorbing Functional Group

A physisorbing functional group temporarily binds to a relevant surface through Van der Waals forces. The relevant surface is the material being modified (e.g., the dielectric material, barrier layer, or liner). The physisorbing functional group strongly adsorbs onto the material being modified, thereby ensuring that the functionalization reactant and its associated active functional group are closely associated (e.g., in close physical proximity) with the material being modified.

In various embodiments, the physisorbing functional group may be or include a phosphonate, a carboxylate, an amine, a hydrocarbon (e.g., an alkyne, an alkene, etc.), or catechol.

In some cases, the physisorbing functional group is or includes a phosphonate A phosphonate is an organophosphorus compound containing C—PO(OH)₂ or C—PO(OR)₂, where:

each R is independently alkyl, aryl.

In some cases, the physisorbing functional group is or includes a carboxylate. A carboxylate is a salt or ester of a carboxylic acid and includes a formula R—COO⁻.

In some cases, the physisorbing functional group is or includes an amine. The amine may have a formula of NR¹R²R³, where:
each of R¹, R², and R³ is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
in which R¹ and R², taken together with the atom to which each are attached, can optionally form a cycloheteroaliphatic; and
in which R¹, R², and R³, taken together with the atom to which each are attached, can optionally form a cycloheteroaliphatic.

In some embodiments, each of R¹, R², and R³ is independently selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alky-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaiyl, heteroalkynyl-heteroaryl, or any combinations thereof. In particular disclosed embodiments, the amine may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when at least one of R¹, R², and R³ is aliphatic, haloaliphatic, haloheteroaliphatic, orheteroaliphatic, the additive is an alkyl amine. The alkyl amine can include dialkylamines,trialkyl amines, and derivatives thereof. Example alkyl amines include dimethylisopropylamine, N-ethyldiisopropylamine, trimethylamine, dimethylamine, methylamine, triethylamine, t-butyl amine, and the like.

In other embodiments, when at least one of R¹, R², and R³ includes a hydroxyl, the additive is an alcohol amine. In one instance, at least one of R¹, R², and R³ is an aliphatic group substituted with one or more hydroxyls. Example alcohol amines include 2-(dimethylamino)ethanol, 2-(diethylamino)ethanol, 2-(dipropylamino)ethanol, 2-(dibutylamino)ethanol, N-ethyldiethanolamine, N-tertbutyldiethanolamine, and the like.

In some embodiments, when R¹ and R², taken together with the atom to which each are attached, form a cycloheteroaliphatic, the additive can be a cyclic amine. Example cyclic amines include piperidine, N-alkyl piperidine (e.g., N-methyl piperidine, N-propyl piperidine, etc.), pyrrolidine, N-alkyl pyrrolidine (e.g., N-methyl pyrrolidine, N-propyl pyrrolidine, etc.), morpholine, N-alkyl morpholine (e.g., N-methyl morpholine, N-propyl morpholine, etc.), piperazine, N-alkyl piperazine, N,N-dialkyl piperazine (e.g., 1 ,4-dimethylpiperazine), and the like.

In other embodiments, when at least one of R¹, R², and R³ includes an aromatic, the additive is an aromatic amine. In some embodiments, at least one of R¹, R², and R³ is aromatic, aliphatic-aromatic, or heteroaliphatic-aromatic. In other embodiments, both R¹ and R² includes an aromatic. In yet other embodiments, R¹ and R² and optionally R³, taken together with the atom to which each are attached, from a cycloheteroaliphatic that is an aromatic. Example aromatic amines include aniline, histamine, pyrrole, pyridine, imidazole, pyrimidine, and the derivatives thereof.

In some embodiments, the additive may include an amine selected from the group consisting of: methylamine, dimethylamine, trimethylamine, ethylamine, diethylamine, triethylamine, isopropylamine, 1,2-ethylenediamine, aniline (and aniline derivatives such as N,Ndimethylaniline), N-ethyldiisopropylamine, tert-butylamine, and combinations thereof.

In some embodiments, the physisorbing functional group is or includes a hydrocarbon. In some cases, the hydrocarbon may be a cyclic hydrocarbon (e.g., methylcyclohexane); substituted aromatic hydrocarbon (e.g., halo-substituted benzene, amine-substituted benzene, C₂₋₈ alkyl-substituted benzene, or halo- and alkyl-substituted benzene, such as cumene, aniline, N,N-dimethylaniline, etc.); or halocarbon (e.g., a C₂₋₁₂ alkyl having one or more halos). In some embodiments, the hydrocarbon is an unsaturated hydrocarbon having one or more double bonds or triple bonds. In other embodiments, the hydrocarbon is an unsaturated, cyclic hydrocarbon (e.g., cyclopentene, cyclohexene, cycloheptene, fluorene, etc.). In particular embodiments, the hydrocarbon is an alkene having one or more double bonds or an alkyne having one or more triple bonds, in which the alkene or the alkyne can be linear or cyclic. Exemplary alkenes include ethene, propene, 1-butene, 1-pentene, 1-hexene, 1-heptene, 1-octene, and 1-nonene, as well as dienes of any of these and positional isomers if available, in which the location of the double bond is changed (e.g., a positional isomer of 1-butene could be 2-butene, etc.). Exemplary alkynes include ethyne, propyne, 1-butyne, 1-pentyne, 1-hexyne, 1-heptyne, 1-octyne, and 1-nonyne, as well as positional isomers if available, in which the location of the triple bond is changed (e.g., a positional isomer of 1-butyne could be 2-butyne, etc.).

In some embodiments, the physisorbing functional group is or includes an alcohol, as defined and described above. In some cases, the alcohol is an aromatic alcohol. Exemplary alcohols include, but are not limited to, catechol and the other alcohols mentioned above. Catechol has a formula of C₆H₄(OH)₂, and it is an unsaturated six-carbon ring with two hydroxyl groups attached to adjacent carbons. Substituted forms of catechol may be used in some cases, with substitutions including, e.g., hydroxyl, aliphatic, haloaliphatic, haloheteroaliphatic, heteroaliphatic, aromatic, aliphatic-aromatic, heteroaliphatic-aromatic, or any combinations thereof.

### B. Chemisorbing Functional Group

A chemisorbing functional group binds to a relevant surface through covalent or ionic chemical bonds. These bonds are stronger and more permanent than those made by physisorbing functional groups. The chemisorbing functional group chemically reacts with the material being modified, thereby ensuring that the functionalization reactant and its associated active functional group are closely associated (e.g., in close physical proximity) with the material being modified. In various embodiments, the chemisorbing functional group may be or include a hydroxide, a halosilane, an alkoxy-silane, an acyloxy-silane, an N-hydroxysuccinimide ester, a disilazane, a trisilazane, an allylsilane, an arylsilane, a silyl-acetamide, a silyl-imidazole, a methyllylsilane, a vinylsilane, and combinations thereof.

In some cases, the chemisorbing functional group is or includes a hydroxide having a formula of OH⁻.

In certain embodiments where the chemisorbing functional group is or includes a hydroxide, the substrate may be exposed to the functionalization bath at about room temperature (e.g., between about 15-30° C.).

In some cases, the chemisorbing functional group is or includes a halosilane. The halosilane may have a formula of XₘSiRₙ, where:
each X is independently selected from F, Cl, Br, or I;
each R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
m is an integer between 1-4; and
n = 4 - m.

In certain embodiments where the chemisorbing functional group is or includes a halosilane, the functionalization bath may further include a base. In certain cases the base may provide OH⁻. Other types of bases may also be used. In one example, abase such as triethylamine may be used. Example halosilanes include, but are not limited to, Cl—SiR₃, and Br—SiR₃.

In some cases, the chemisorbing functional group is or includes an alkoxy-silane. The alkoxy-silane may have a formula of (R¹O)ₘ—(SiR²)ₙ, where:
each R¹ is alkyl or an alkyl derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
m is an integer between 1-4; and
n = 4 - m.

In some cases, the alkoxy-silane may have a formula of R¹O—SiR²₃.

In certain implementations where the chemisorbing group is or includes an alkoxy-silane, the substrate may be exposed to the functionalization bath at an elevated temperature (e.g., a temperature of about 40° C. or greater). In these or other embodiments, the alkoxy-silane may be used in combination with water and/or bases as reactants.

In some cases, the chemisorbing functional group is or includes an acyloxy-silane. The acyloxy-silane may have a formula of (R¹CO₂)ₘ—SiR²ₙ, where:
each R¹ is alkyl or an alkyl derivative; and
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
m is an integer between 1-4; and
n = 4 - m.

In some cases, the acyloxy-silane may have a formula of R¹CO₂—SiR²₃.

In some cases, the chemisorbing functional group is or includes an N-hydroxysuccinimide ester. The N-hydroxysuccinimide ester may have a formula of (R¹CO₂)ₘ-XR² n where:
X is Si, or O, and
each of R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof.

In cases where X is silicon, then the chemisorbing functional group may be an acyloxy-silane, as noted above. In cases where X is oxygen, the chemisorbing functional group may be a hydroxy ester.

In some cases, the chemisorbing functional group is or includes a disilazane. The disilazane may have a formula of NH(SiR₃)₂, where:

each R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof.

Example disilazanes include, but are not limited to, hexamethyldisilazane, tetramethyldisilazane, tetraphenyldimethyldisilazane, tetramethyldivinylsilazane, and hexamethyldisilazane.

In some cases, the chemisorbing functional group is or includes a trisilazane. The trisilasane may have a formula of N(SiR₃)₃, where:

each R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof.

In some cases, the chemisorbing functional group is or includes an allylsilane. In certain embodiments, the allylsilane may have a formula of (H₂C—CH—CH₂)ₘ—SiRₙ, where:
each R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
m is an integer between 1-4; and
n = 4 - m.

In some cases, the allylsilane may have a formula of H₂C═CH—CH₂—SiR₃. In a particular example, the allylsilane may be 2-propenyl(3-chloropropyl)-dimethyl-silane.

In some cases, the chemisorbing functional group is or includes an arylsilane. The arylsilane may have a formula of R¹ₘSiR²ₙ, where:
each R¹ is aryl or an aryl derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
m is an integer between 1-4; and
n = 4 - m.

In one example, the arylsilane may have a formula of R¹SiR²₃.

In some cases, the chemisorbing functional group is or includes a silyl-acetamide. The silyl-acetamide may have a formula of R1₃Si-NCMeO-SiR2_{3,} where:
Me is CH₃, and
each R1 and R2 is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof.

In some cases, the chemisorbing functional group is or includes a silyl-imadazole. The silyl-imidazole may have a formula of R¹ₘSiR²ₙ, where:
each R¹ is imidazole or an imidazole derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
m is an integer between 1-4; and
n = 4 - m.

In some cases, the chemisorbing functional group is or includes a methallylsilane. The methallylsilane may have a formula of (CH₃C═CH₂CH₂)ₘSiRₙ, where:
each R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
m is an integer between 1-4; and
n = 4 - m.

In some cases, the chemisorbing functional group is or includes a vinylsilane. The vinylsilane may have a formula of (H₂C═CH)ₘSiRₙ, where:
each R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
m is an integer between 1-4; and
n = 4 - m.

In various embodiments herein, the binding functional group of the functionalization reactant includes at least one physisorbing and/or chemisorbing functional group. In some cases, a combination of physisorbing functional groups, or a combination of chemisorbing functional groups, or a combination of physisorbing and chemisorbing functional groups may be used. The binding functional group acts to bind the functionalization reactant to the material being modified. This ensures that the active functional group of the functionalization reactant is in close contact with the material being modified.

### 2. Active Functional Group

The functionalization reactant includes one or more active functional group that acts to facilitate deposition in a subsequent deposition step. Various different types of active functional groups can be used, including, e.g., reducing functional groups, catalyzing functional groups, decomplexing functional groups, and adhesive functional groups. Each of these types of functional groups will be discussed in turn.

In some embodiments, the active functional group may be the same as the binding functional group. In other words, a single functional group may perform as both a binding functional group and an active functional group. In other embodiments, the active functional group is different from the binding functional group. In some such cases, the active functional group may be separated from the binding functional group by a chain of carbon atoms between 1-10 atoms long. In some cases, the active functional group may be a separate molecule that is bound to the binding functional group (or another portion of the functionalization reactant) through Van der Waals forces or other intermolecular interactions.

### A. Reducing Functional Group

Reducing functional groups are functional groups that are capable of chemically reducing a metal ion to its metallic form at the surface of the material being modified. Reducing functional groups result in formation of a high quality, uniform nucleation layer for a subsequent deposition step. After the relevant material is modified to include a reducing functional group, the deposition step (e.g., a wet electroplating or electroless plating process, or a dry vapor phase process) may be used to preferentially reduce metal to its metallic form in regions where the reducing functional group is present (e.g., in regions where the functionalization reactant has bound to the material being modified). This technique results in the formation of high quality film that would not otherwise be achievable due to, e.g., poor nucleation in the absence of the functionalization reactant.

In various embodiments, the reducing functional group may be or include a borohydride, a borane, an aldehyde (e.g., formaldehyde), an acid (e.g., glyoxylic acid, pyruvic acid, ascorbic acid, etc.), hypophosphite, hydrazine, a glycol (e.g., ethylene glycol), a reductive metal ion (e.g., a metal ion that brings about reduction by being oxidized and losing electrons such as Fe(II), Cr(II), Ti(III), V(II), etc.), substituted forms of these examples, and combinations thereof.

In cases where the reducing functional group is or includes a borohydride, the borohydride may have a formula of BHₘRₙ⁻, where:
each R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
m is an integer between 1-4; and
n = 4 - m.

In a particular example, the borohydride may have a formula of BH₄⁻. In some cases, the borohydride may be provided in the form of a salt.

In cases where the reducing functional group is or includes a borane, the borane may have a formula of BₓH_{y}, where:

x and y are integers.

In some embodiments, the borane may be substituted with one or more hydroxyl, aliphatic, haloaliphatic, haloheteroaliphatic, heteroaliphatic, aromatic, aliphatic-aromatic, heteroaliphatic-aromatic, or any combinations thereof.

In cases where the reducing functional group is or includes an aldehyde, the aldehyde may have a formula of R-CHO. A particular example of an aldehyde that may be used in certain cases is formaldehyde.

In cases where the reducing functional group is or includes a glycol, the glycol may be an alcohol having two —OH groups, each on different carbon atoms. One example glycol that may be used in some cases is ethylene glycol.

### B. Catalyzing Functional Group

Catalyzing functional groups are functional groups that are capable of catalyzing the reduction of a metal ion or the release of a metal atom from a complex. Catalyzing functional groups do not directly interact with the metal ion, but instead cause the metal ion to be reduced or de-complexed through catalysis.

In some embodiments, the catalyzing functional group may be or include nanoparticles of a metal and/or metal oxide. The nanoparticles may have a diameter between about 5-30 Å. In certain implementations, the nanoparticles may be gold, copper, copper oxide, zinc, zinc oxide, platinum, platinum oxide, pal ladium, palladium oxide, ruthenium, ruthenium oxide, molybdenum, molybdenum oxide, silver, silver oxide, vanadium, vanadium oxide, tungsten, tungsten oxide, or an alloy or other combination of two or more of the listed materials.

### C. Decomplexing Functional Group

Decomplexing functional groups are functional groups that are capable of reacting with and binding to a ligand to thereby release a metal that was previously complexed to the ligand. Reaction with the ligand frees the metal for deposition on the surface being modified.

In some embodiments, the decomplexing functional group may be or include a hydroxide, an alcohol, an ester, an ether, a carboxylic acid, and combinations thereof.

In certain embodiments where the decomplexing functional group is or includes a hydroxide, the hydroxide may have a formula —OH⁻.

In certain embodiments where the decomplexing functional group is or includes an alcohol, the alcohol may have a formula described above in relation to the alcohol solvent.

In certain embodiments where the decomplexing functional group is or includes an ester, the ester may have a formula of X—[O]ₙ—C(O)—O—Y, where:
n is 0 or 1;
each X and Y can be independently selected from —[C(R¹)₂]ₘ—C(R²) or -{[C(R¹)₂]ₘ—[O]ₙ}ₚ-C(R²) or —[C(R¹)₂]m—C(O)—N(R²)₂ or —[C(R¹)₂]ₘ—C(O)—O—[C(R²)₂]ₘ—C(R³), wherein each R¹, R², and R³ is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10 and p is an integer from 1 to 10; and
in which X and Y, taken together with the atom to which each are attached, can optionally form a cycloheteroaliphatic group.

In some embodiments, each R¹, R², and R³ independently is selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the ester may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X and Y are taken together with the atom to which each are attached in order to form a cycloheteroaliphatic group, the ester can be a cyclic ester. Exemplary cyclic esters include lactones, such as s-caprolactone, y-caprolactone, γ-valerolactone, 8-valerolactone, and the like.)

In some embodiments, when at least one of X or Y is —[C(R¹)₂]ₘ—C(O)—N(R²)₂, then the ester can be an aminoester. Exemplary amino esters include methyl-5-(dimethylamino)-2-methyl-5-oxopentanoate and the like.

In some embodiments, when X = —CH₃ and n = 0, the ester can be an acetate in which Y = -[C(R¹)₂]ₘ-C(R²) and m is an integer from 2 to 10. In other embodiments, when X = —CH₃ and n = 0, the ester can be an acetate in which Y = —[C(R¹)₂]ₘ—C(R²), m is an integer from 1 to 10, and at least one R¹ or R² is C₁₋₁₀ aliphatic, haloaliphatic, haloheteroaliphatic, heteroaliphatic, aromatic, aliphatic-aromatic, heteroaliphatic-aromatic, or any combinations thereof. Exemplary acetates include n-propyl acetate, isopropyl acetate, n-butyl acetate, t-butyl acetate, iso-butyl acetate, propylene glycol methyl ether acetate, etc., including corresponding acetates of methyl, ethyl, propyl, and butyl mono- and di-ethers of ethylene glycol.

In some embodiments, when at least one of X or Y = -{[C(R¹)₂]ₘ—[O]ₙ}ₚ₋C(R²), the ester can be a glycol based ester. Exemplary glycol based esters include propylene glycol methyl ether acetate, and the like.

In other embodiments, when at least one of X or Y includes a hydroxyl, the ester can be a hydroxy ester. Exemplary hydroxy esters include alpha-hydroxy esters, such as those derived from lactate (e.g., methyl lactate, ethyl lactate, n-propyl lactate, isopropyl lactate, n-butyl lactate, isobutyl lactate, t-butyl lactate, etc.).

In some embodiments, when n = 1, the ester can be a carbonate ester. In particular embodiments, X and Y are taken together with the atom to which each are attached in order form a cycloheteroaliphatic group, thereby providing a cyclic carbonate ester. Exemplary carbonate esters include propylene carbonate, diethyl carbonate, glycerol carbonate, and the like.

In other embodiments, when X = —[C(R¹)₂]ₘ—C(O)—O—[C(R²)₂]ₘ—C(R³) (and, e.g., n = 0), the ester can be a diester. Exemplary diesters include dimethyl 2-methylglutarate, dimethyl succinate, dimethyl adipate, and the like).

In certain embodiments where the decomplexing functional group is or includes an ether, the ether may have a formula of X—O—Y or X—O—[C(R)₂]ₙ—O—Y, where:
n is an integer from 1 to 4;
each X and Y can be independently selected from —[C(R¹)₂]ₘ—C(R²) or —R³ or —[C(R⁴)₂]ₚ—O—[C(R⁵)₂]ₘ—C(R⁶), wherein each of R¹, R², R³, R⁴, R⁵, R⁶ and R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10 and p is an integer from 1 to 10;
in which X and Y, taken together with the atom to which each are attached, can optionally form a cycloheteroaliphatic group.

In some embodiments, each R, R¹, R², R³, R⁴, R⁵ and R⁶ independently are selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the ether may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X and Yare taken together with the atom to which each are attached in order form a cycloheteroaliphatic group, the organic solvent is a cyclic ether, such as, acetal, dioxane, dioxolane, etc. In some embodiments, when n = 1 and each R = H, X and Y taken together form a six, seven, eight, nine, or ten-membered ring. Example ethers include, but are not limited to, 1,3-dioxolane, or derivatives thereof. In other embodiments, when n = 2 and R = H, X and Y form a seven, eight, nine, or ten-membered ring. Example ethers include, but are not limited to, 1,4-dioxane, or derivatives thereof. In yet other embodiments, when n = 1 or n = 2, then R is aliphatic, haloaliphatic, haloheteroaliphatic, heteroaliphatic, aromatic, aliphatic-aromatic, heteroaliphatic-aromatic, or any combinations thereof. Example cyclic ethers include tetrahydrofuran, 2-methyltetrahydrofuran, 2-methyl-1,3-dioxolane, and the like.

In other embodiments, when at least one of X or Y = aromatic, the organic solvent can be an aromatic ether. Example aromatic ethers include anisole, diphenyl ether, and the like.

In some embodiments, when at least one of X or Y = cycloaliphatic, the organic solvent can be a cycloalkyl ether. Example cycloalkyl ethers include cyclopentyl methyl ether, cyclohexyl methyl ether, and the like.

In other embodiments, when at least one of X or Y = —[C(R⁴)₂]ₚ—O—[C(R⁵)₂]ₘ—C(R⁶), the organic solvent can be a glycol based ether. Example glycol based ethers include diethylene glycol diethyl ether, dipropylene glycol dimethyl ether, poly(ethylene glycol) dimethyl ether, etc., including methyl, ethyl, propyl, and butyl mono- and di-ethers of ethylene glycol, and the like.

In certain embodiments where the decomplexing functional group is or includes a carboxylic acid, the carboxylic acid may have a formula of R-COOH, where:

R is alkyl.

### D. Adhesive Functional Group

Adhesive functional groups are functional groups that are capable of effectively binding to the material that is to be deposited directly on the material being modified. With reference to FIG. 1, in one example where the dielectric material 103 is modified, the adhesive functional group is capable of effectively binding to the material used for the barrier layer 105 (or a precursor to the barrier layer 105). In another example where the barrier layer 105 is modified, the adhesive functional group is capable of effectively binding to the material used for the optional liner 107, or to the material used for the seed layer or to the material used for the conductive metal 109. Adhesive functional groups can improve adhesion to and/or nucleation on the material being modified when a subsequent material is deposited thereon.

In some embodiments, the adhesive functional group may be the same as the binding functional group. In such cases, the material acting as the adhesive and binding functional groups may act as a thin liner, adhering well to both the material being modified and to the material subsequently deposited on the material being modified.

In various embodiments, the adhesive functional group may be or include a hydroxide, an alcohol, a carboxylic acid, a metal oxide, and combinations thereof.

In cases where the adhesive functional group is or includes a hydroxide, the hydroxide may have a formula as stated above in relation to the hydroxide decomplexing functional group.

In cases where the adhesive functional group is or includes an alcohol, the alcohol may have a formula as recited above in relation to the alcohol solvent.

In cases where the adhesive functional group is or includes a carboxylic acid, the carboxylic acid may have a formula as recited above in relation to the decomplexing functional group.

In cases where the adhesive functional group is or includes a metal oxide, the metal oxide may have a formula of MeₘOₙ, where:
Me is a metal of interest; and
m and n are integers that may or may not represent a stoichiometric balance between metal and oxygen.

In various embodiments, the metal of interest may be the same as a metal that is deposited in a subsequent step. For instance, with reference to FIG. 1, in one example the layer of dielectric material 103 is modified through the use of a functionalization reactant that includes a metal oxide adhesive functional group that includes a metal that will be deposited as part of the barrier layer 105. In another example, the barrier layer 105 is modified with a functionalization reactant that includes a metal oxide adhesive functional group that includes a metal that will be deposited as part of the optional liner 107, or as the seed layer, or as the conductive metal 109. In another example, the optional liner 107 is modified with a functionalization reactant that includes a metal oxide adhesive functional group that includes a metal that will be deposited as the seed layer or as the conductive metal 109. In other cases, the metal of interest may be different from the metal deposited in a subsequent step/layer.

Example metal oxides that may be used in some embodiments include, but are not limited to, tantalum oxide, titanium oxide, tin oxide, copper oxide, molybdenum oxide, zinc oxide, magnesium oxide, manganese oxide, indium oxide, aluminum oxide, cobalt oxide, iridium oxide, ruthenium oxide, palladium oxide, etc.

### C. pH Adjustment Species

The functionalization bath may further include a pH adjustment species in certain embodiments. The pH adjustment species may be provided to adjust the pH of the functionalization bath to within a desired range. This pH control may encourage desired reactions and suppress undesired reactions. In some cases, one or more pH adjustment species may be provided to maintain the pH of the functionalization bath between about 0-5 for acid-stable species or between about 9-12 for alkaline-stable species.

In some cases, the pH adjustment species may include a base or an acid. Example bases include, but are not limited to, triethylamine, tetramethylammonium hydroxide, ammonium hydroxide, and combinations thereof. Example acids include, but are not limited to, sulfuric acid, hydrochloric acid, nitric acid, phosphoric acid, and combinations thereof.

### D. Processing With the Functionalization Bath

In order to functionalize a desired material on the substrate, the substrate is contacted with the functionalization bath while the desired material is exposed on the substrate surface. The substrate may be wholly or partially immersed in the functionalization bath, of the functionalization bath may be sprayed onto the substrate. The substrate is contacted with the functionalization bath for a sufficient duration to adequately functionalize the surface, as desired. In some embodiments, this duration may be between about 5 seconds to about 2 minutes. The duration may depend on the identity of the functionalization reactant and the binding and/or active functional groups that may be part of the functionalization reactant.

After the substrate is contacted with the functionalization bath, the functionalization bath may be optionally rinsed from the substrate surface. In various embodiments, the substrate may be rinsed with water or another rinsing liquid. In some cases, the rinsing liquid may be or include the same solvent that is used in the functionalization bath.

After the desired material is functionalized and the substrate is optionally rinsed, the substrate may be optionally dried. In one example, the substrate is dried by spinning off any excess liquid on its surface. In another example, the substrate may be dried by applying heat, convection, etc.

A number of processing variables may be controlled while processing the substrate with the functionalization bath. Example processing variables that may be controlled include, but are not limited to, the pressure within the processing chamber where functionalization is occurring, the temperature of the functionalization bath and/or substrate, the composition of the atmosphere within the processing chamber where functionalization is occurring, the composition of the functionalization bath, the amount of dissolved oxygen within the functionalization bath, and mass transport within the functionalization bath (e.g., flow rates, mixing rates, etc.).

In some cases, the substrate may be contacted with the functionalization bath at a reduced pressure (e.g., a pressure lower than atmospheric pressure, for example about 100 Torr or less). This reduced pressure may help prevent bubble formation and thereby ensure that small features are adequately wetted with the functionalization bath.

The temperature of the functionalization bath and/or substrate may be controlled while the functionalization bath is contacting the substrate. In some cases, the functionalization bath and/or substrate may be maintained at a temperature between about 15-70° C. while the functionalization bath is contacting the substrate. The optimal temperature may depend on a desired reaction, for example between the material being modified and the binding group of the functionalization reactant.

The composition of the atmosphere within the reaction chamber where functionalization occurs may be controlled. In some cases, the atmosphere is air. In other cases, the atmosphere may be inert (e.g., He, Ne, Ar, Kr, Xe, N₂, etc.).

The composition of the functionalization bath may be controlled. The solvent, functionalization reactant, and pH adjustment species may each be selected for a particular application, for example to modify a particular material to facilitate deposition of a subsequent material. In some cases, the functionalization reactant (and/or the functional groups that contribute to the functionalization reactant) may be provided at a concentration between about 1∼1000 mM. Where a pH adjustment species is used, it may be provided at a concentration between about 1-1000 mM. In certain cases, the concentration of dissolved oxygen within the functionalization bath may be controlled between about 0-9 ppm.

The mass transport characteristics within the reaction chamber where functionalization occurs may be likewise controlled. These characteristics may be control led by regulating, e.g., a flow rate of functionalization bath delivered to the reaction chamber, stirring speeds within the reaction chamber, rotation of the substrate within the chamber, etc.

FIG. 2 illustrates a flowchart describing various embodiments in which a substrate is processed in a wet functionalization bath to facilitate further processing in the context of forming a BEOL interconnect structure.

The method begins with operation 201, where a substrate is received in a reaction chamber. The substrate that is received includes recessed features formed thereon. The recessed features correspond to locations where the BEOL interconnect structures are to be formed. With reference to FIG. 1, in one example the substrate 101 received in the reaction chamber includes dielectric material 103 exposed on the substrate surface. In other words, in this example the barrier layer 105, optional liner 107, and conductive metal 109 are not yet deposited. In another example, the substrate 101 includes dielectric material 103 and barrier layer 105, with barrier layer 105 exposed on the substrate surface. In this example, the optional liner 107 and the conductive metal 109 are not yet deposited. In another example, the substrate 101 includes dielectric material 103, barrier layer 105, and optional liner 107, with the optional liner 107 exposed on the substrate surface. In this example, the conductive metal 109 is not yet deposited.

At operation 203, the substrate is contacted with the functionalization bath for a duration sufficient to allow the exposed material to become functionalized with the functionalization reactant in the functionalization bath. As mentioned above, this contact may occur by wholly or partially immersing the substrate in the functionalization bath (e.g., similar to immersing a substrate for electroplating or electroless plating), or by spraying the functionalization bath over the surface of the substrate. As the functionalization bath contacts the exposed material on the substrate, the functionalization reactant binds to the exposed material (e.g., through the binding functional group on the functionalization reactant), thereby functionalizing the exposed material and forming a modified material on the surface of the substrate. As mentioned above, the substrate may be optionally rinsed and/or dried after it is contacted with the functionalization bath.

At operation 205, the substrate is further processed using a wet technique (e.g., electroless plating or electroplating) or a dry technique (e.g., chemical vapor deposition or atomic layer deposition), as discussed below. The further processing deposits an additional material on the substrate, for example as the additional material reacts with the modified material. With reference to FIG. 1, in one example operation 203 involves modifying the dielectric material 103, and operation 205 involves depositing barrier layer 105 (or a precursor to barrier layer 105). In another example, operation 203 involves modifying the barrier layer 105, and operation 205 involves depositing the optional liner 107, or the seed layer, or the conductive metal 109. In another example, operation 203 involves modifying the optional liner 107, and operation 205 involves depositing the seed layer or the conductive metal 109.

For many materials and deposition techniques described herein, absent the modification with the functionalization bath, the further processing steps in operation 205 would be unsuccessful or very poor quality due to, e.g., poor nucleation and adhesion between the relevant materials. The surface modification/functionalization that occur during operation 203 facilitate and enable the deposition in operation 205.

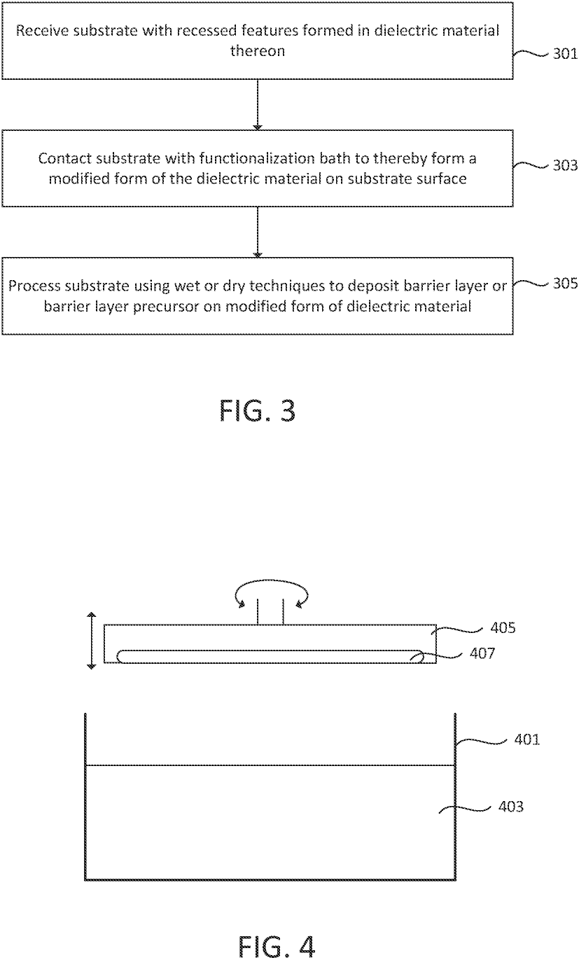

FIG. 3 illustrates a specific embodiment of FIG. 2 where dielectric material is modified to facilitate subsequent deposition of a barrier layer (or barrier layer precursor). The method of FIG. 3 begins with operation 301, where the substrate is received in the reaction chamber. With reference to FIG. 1, the substrate 101 includes dielectric material 103 thereon, with recessed features formed in the dielectric material 103. The substrate does not yet include the barrier layer 105, optional liner 107, or conductive metal 109. At operation 303, the substrate is contacted with the functionalization bath to thereby form a modified form of the dielectric material on the substrate surface. The dielectric material is modified as the functionalization reactant binds to the dielectric material (e.g., through the binding functional group of the functionalization reactant), thereby forming a surface that is functionalized. The substrate may be optionally rinsed and/or dried after operation 303. At operation 305, the substrate is further processed using a wet or dry technique, as described below, to deposit the barrier layer or a material that acts as a precursor to the barrier layer.

### II. Post-Functionalization Processing

After a relevant material has been modified with the functionalization reactant, an additional material is deposited on the substrate surface. The additional material (or a reactant used to form the additional material) may react with the modified material on the substrate surface to promote a high degree of nucleation and high quality adhesion between the two materials. For example, the additional material (or a reactant used to form the additional material) may react with the active functional group of the functionalization reactant, which may be bound to the modified material via the binding functional group of the functionalization reactant. This ensures a high quality interface between the two relevant materials.

The layer that is deposited during the post-functionalization processing depends on the layer that was modified/functionalized in a previous step. With reference to FIG. 1, in one example the layer of dielectric material 103 is modified during the wet functionalization step (e.g., exposing the substrate to the functionalization bath), and the barrier layer 105 is deposited in the post-functionalization processing step. In another example, the barrier layer 105 is modified during the wet functionalization step, and the optional liner 107, or the seed layer, or the conductive metal 109 are deposited during the post-functionalization processing step. In another example, the optional liner 107 is modified during the wet functionalization step, and the seed layer or conductive metal 109 is deposited during the post-functionalization processing step.

Generally, unless stated otherwise, the post-functionalization processing step refers to the deposition step for forming the additional material that is deposited on the modified/functionalized material. In cases where more than one layer of material is modified/functionalized, there may be more than one post-functionalization processing step (e.g., one post-functionalization process step performed after each of the modification/functionalization steps).

A number of different processing methods are available for depositing the additional material. In some embodiments, the additional material is deposited through wet processing techniques such as electroless plating or electroplating. In some embodiments, the additional material is deposited through dry processing techniques such as chemical vapor deposition (CVD) or atomic layer deposition (ALD), either of which may be driven by thermal energy (e.g., thermal CVD or thermal ALD) or plasma energy (e.g., plasma enhanced CVD or plasma enhanced ALD).

### A. Wet Processing: Electroless Plating and Electroplating

Wet processing techniques such as electroless plating or electroplating may be used to deposit additional material after the material exposed on the substrate has been modified with the functionalization reactant in the wet functionalization step. Electroless plating is particularly useful in contexts where the substrate does not have a conductive seed layer thereon. For instance, electroless plating may be used to deposit the barrier layer (or a precursor to the barrier layer) directly on the modified/functionalized dielectric material. By contrast, electroplating is particularly useful in contexts where the substrate includes a conductive seed layer. For example, in cases where the barrier layer or optional liner (as modified by the functionalization reactant) are sufficiently conductive, these layers may act as a seed layer for a subsequent electroplating step, for example to deposit the optional liner or the conductive metal.

The solution used to deposit the additional material on the material modified by the functionalization reactant maybe referred to as the deposition bath. The deposition bath includes at least a solvent and a mass source. Additional species may be included in the deposition bath depending on the deposition mechanism. Various deposition mechanisms are available.

In some embodiments, a single processing chamber is used to perform both the functionalization step and the deposition step. In such examples, the functionalization bath and the deposition bath may each be provided in the same chamber at different times. In other embodiments, a first processing chamber may be provided to perform the functionalization step and a second processing chamber may be provided to perform the deposition step. In this example, the functionalization bath may be provided in the first processing chamber and the deposition bath may be provided in the second processing chamber. In this case there is no need to cycle different baths through each processing chamber. Instead, the substrate can be transferred between processing chambers, as needed.

### 1. Solvent

The solvent in the deposition bath may be selected to properly solvate the mass source and any other chemistry that may be present in the deposition bath. Further, the solvent is selected to properly wet the modified material. Generally, features described above with respect to the solvent in the functionalization bath may also apply to the deposition bath.

In various embodiments, the solvent in the deposition bath may include water, toluene, hexane, an alcohol (e.g., methanol, ethanol, etc.), acetone, carbon tetrachloride, chloroform, glycerin, acetonitrile, dimethyl sulfoxide, a derivative of these materials, and combinations thereof.

### 2. Mass Source and Deposition Mechanism

The mass source (or a portion thereof) is incorporated into the growing film as the additional material is deposited on the modified material. In many embodiments, the mass source includes a metal of interest. For example, where the additional material being deposited includes tantalum, the mass source includes tantalum. In another example where the additional material being deposited includes titanium, the mass source includes titanium. In another example where the additional material being deposited includes copper, the mass source includes copper. In another example where the additional material being deposited includes tin, the mass source includes tin. In another example where the additional material being deposited includes molybdenum, the mass source includes molybdenum. In another example where the additional material being deposited includes zinc, the mass source includes zinc. In another example where the additional material being deposited includes magnesium, the mass source includes magnesium. In another example where the additional material being deposited includes manganese, the mass source includes manganese. In another example where the additional material being deposited includes indium, the mass source includes indium. In another example where the additional material being deposited includes aluminum, the mass source includes aluminum. In another example where the additional material being deposited includes cobalt, the mass source includes cobalt. In another example where the additional material being deposited includes iridium, the mass source includes iridium. In another example where the additional material being deposited includes ruthenium, the mass source includes ruthenium. In another example where the additional material being deposited includes palladium, the mass source includes palladium. Other metals/materials may be used as desired.

There are three general types of mass sources that may be used in various embodiments including, e.g., metal salts, ligated precursors, and non-metal sources that react with metal. The type of mass source that is used may depend on the type of functionalization reactant that is used. More particularly, it may depend on the type of active functional group used on the functionalization reactant. Different types of active functional groups interact with mass sources to cause deposition in different ways.

### A. Metal Salts

In certain cases, the mass source may be a metal salt. The metal in the metal salt is incorporated into the growing film of the additional material. In other words, the metal salt provides the metal mass source for depositing a metal or other metal-containing material. Example metal salts include, but are not limited to, metal halides (e.g., metal fluorides, metal chlorides, metal bromides, metal iodides), metal sulfites, metal sulfates, metal hydroxides, metal nitrates, metal phosphites, and metal phosphates. The metal in the metal salt is the metal of interest being deposited. For example, where the metal being deposited includes copper, the metal salt may be a copper salt. Similarly, where the metal being deposited includes tantalum or titanium, the metal salt may be a tantalum salt or titanium salt, respectively. Example metals that may be included in the metal salt include, but are not limited to, copper, tantalum, titanium, tin, molybdenum, zinc, magnesium, manganese, indium, aluminum, cobalt, iridium, ruthenium, palladium, tungsten, platinum, etc.

Advantageously, metal salts dissolve upon introduction to the solvent, which frees the metal ions for deposition at the surface of the substrate. These metal ions can interact with the active functional group of the functionalization reactant, which is bound on the substrate surface.

In one example, the metal ions from a metal salt interact with a reducing active functional group of the functionalization reactant, to thereby reduce the metal salt and cause the metal to deposit on the substrate surface (e.g., directly on the material that was modified by the functionalization reactant).

In another example, the metal ions from a metal salt are reduced with a reducing agent present in the deposition bath, where the reducing agent is not provided as part of the functionalization reactant. In one such example, the functionalization reactant includes a catalyzing functional group, and the catalyzing functional group catalyzes the reduction of the metal ions to cause deposition of metal on the substrate surface (e.g., directly on the material that was modified by the functionalization reactant), where the catalyzing functional groups are present. In either of the preceding examples, the reduction/deposition occurs preferentially on the surface of the substrate, as compared to in the deposition bath generally, due to the local presence of the functionalization reactant on the surface of the substrate.

### B. Ligated Organometallic Precursors

In some embodiments, the mass source may be a ligated organometallic precursor. The ligated organometallic precursor may include a metal (e.g., a neutral metal) that is incorporated into the growing film of the additional material. The ligated organometallic precursor provides a solvated (or volatilized, in the case of vapor deposition) form of the metal ion or atom, which can be deposited onto a substrate.

Ligated precursors are commonly used in vapor deposition techniques such as chemical vapor deposition and atomic layer deposition. However, volatile precursors of the sort used for vapor deposition techniques are not commonly used in wet processing. Before the metal in the ligated precursor is incorporated into the growing film of the additional material, it is released from its organic framework. This release may be driven through various different techniques. The released metal may be neutral or charged.

In one example where a ligated organometallic precursor is used, thermal energy may be used to drive release of the metal from its organic framework. Example temperatures for driving the release may be between about 40-90° C. In such cases, the free metal may interact with an adhesive functional group of the functionalization reactant to thereby deposit the metal on the modified material.

In another example where a ligated organometallic precursor is used, the ligated organometallic precursor indirectly interacts with a catalytic functional group of the functionalization reactant to thereby catalyze release of the metal from its organic framework. In such cases, the free metal is concentrated at the surface of the substrate, where it can then be incorporated in the growing film of the additional material.

In another example where a ligated organometallic precursor is used, the ligated organometallic precursor directly reacts with a decomplexing functional group of the functionalization reactant. As a result, the metal in the ligated organometallic precursor is released near the surface of the substrate, where it can then be incorporated into the growing film of the additional material.

Many different types of ligated organometallic precursors may be used. Examples include, but are not limited to, metal halides, metal alkyls, metal cyclopentadienyls, metal hexane derivatives, other cyclic organometallics, metal alkoxides, metal beta-diketonates, metal amides, metal imides, metal amidinates, metal phosphines, metal vinyl silanes, metal carboxyls, metal amidinatos, metal pyrrolyl derivatives, metal bidentates, and metal polycyclic ligands.

The metal in the ligated organometallic precursor may be any of the metals discussed above with respect to metal salts.

In certain embodiments, the ligated organometallic precursor is or includes a metal halide. The metal halide may have a formula of MₘXₙR_{z}, where:
M is a metal;
X is a halogen (e.g., fluorine, chlorine, bromine, iodine, etc.);
each R is independently selected from hydrogen, hydroxyl, aliphatic, haloaliphatic, haloheteroaliphatic, heteroaliphatic, aromatic, aliphatic-aromatic, heteroaliphatic-aromatic;
m and n are integers that may or may not represent a stoichiometric balance; and
z may be 0 or any positive number.

Example metal halides include metal fluorides, metal chlorides, metal bromides, and metal iodides. Substituted forms of metal halides may also be used, with example substitutions including, e.g., hydroxyl, aliphatic, haloalipliatic, haloheteroaliphatic, heteroaliphatic, aromatic, aliphatic-aromatic, heteroaliphatic-aromatic, or any combination thereof

In certain embodiments, the ligated organometallic precursor is or includes a metal alkyl. The metal alkyl may have a formula of MₘR¹ₙR²_{z}, where:
M is a metal;
each R¹ is alkyl or an alkyl derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal alkyl precursors include, but are not limited to, methyl metals, tetramethyl metals, ethyl metals, diethyl metals, isopropyl metals, allyl metals, n-butyl metals, isobutyl metals, tert-butyl metals, neopentyl metals, carbonyl metals, 3-aminopropyl metals, etc. Substituted forms of these may also be used, with example substitutions including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal cyclopentadienyl. The metal cyclopentadienyl may have a formula of MₘR¹ₙR²_{z}, where:
M is a metal;
each R¹ is cyclopentadienyl or a cyclopentadienyl derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal cyclopentadienyls include, but are not limited to, cyclopentadienyl metals, methylcyclopentadienyl metals, pentamethylcyclopentadienyl metals, ethylcyclopentadienyl metals, isopropylcyclopentadienyl metals, tri-isopropyicyclopentadienyl metals, tris(tert-butyl) cyclopentadienyl metals, n-propyltetramethylcyclopentadienyl metals, N-N′-dimethyl-1-cyclopentadienylethanamine metals, and trimethylsilylcyclopentadienyl metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal hexane derivative. The metal hexane derivative may have a formula of MₘR¹ₙR²_{z}, where:
M is a metal;
each R¹ is hexane or a hexane derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal hexane derivatives include, but are not limited to, 1,3-cyclohexadiene metals, phenyl metals, 2,4-dimethylpentadienyl metals, and 1-isopropyl-4-methylphenyl metals.

In certain embodiments, the ligated organometallic precursor is or includes another cyclic organometallic compound. Examples include, but are not limited to, 1,5-cyclo-octadiene metal, and 2,2-bis(cyclopentadienyl)propane metal. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal alkoxide. The metal alkoxide may have a formula of MₘR¹ₙR²_{z}, where:
M is a metal;
each FL¹ is alkoxide or an alkoxide derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal alkoxides include, but are not limited to, methoxy metals, ethoxy metals, n-propoxy metals, n-butoxy metals, isobutoxy metals, tert-butoxy metals, tertpentoxy metals, 1-methoxy-2-methyl-2-propoxy metals, 2,3-Dimethyl-2-butoxy metals, 3-Methyl-2-pentoxy metals, and N,N′-diethylhydroxyamido metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal beta-diketonate The metal beta-diketonate may have a formula of MₘR¹ₙR²_{z}, where:
M is a metal;
each R¹ is beta-diketonate or a beta-diketonate derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal beta-diketonates include, but are not limited to, acetylacetonato metals, 2,2,6-trimethyl-3,5-heptanedionato metals, 2,2,6,6-tetramethyl-3,5-heptanedionato metals, 2,2,6,6-tetramethyl-3,5-octanedionato metals, octane-2,4-dionato metals, 6-ethyl-2,2-dimethyl-3,5-decanedionato metals, 1-(2-methoxyethoxy)-2,2,6,6-tetramethyl-3,5-heptandedionato metals, and 1,1,1,5,5,5-Hexafluoroacetylacetonato metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal amide. The metal amide may have a formula of MₘR¹ₙR²_{z}, where:
M is a metal;
each R¹ is amide or an amide derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal amides include, but are not limited to, amido metals, dimethylamido metals, ethylmethylamido metals, diethylamido metals, tert-butylamido metals, and bis(trimethylsilyl)amido metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal imide. The metal imide may have a formula of MₘR¹ₙR²_{z}, where:
M is a metal;
each R¹ is imide or an imide derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal imides include, but are not limited to, ethylimido metals, isopropylimido metals, tert-butylimido metals, tertamylimido metals, nitrosyl metals, and isocyanato metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal amidinate. The metal amidinate may have a formula of MₘR¹ₙR²_{z}, where:
M is a metal;
each R¹ is amidinate or an amidinate derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

One example metal amidinate is N,N′-diisopropylacetamidinato metals. Substituted forms may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal phosphine. The metal phosphine may have a formula of MₘR¹ₙR²_{z}, where:
M is a metal;
each R¹ is phosphine or a phosphine derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal phosphines include, but are not limited to, triethylphosphine metals, and tributylphosphine metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal vinyl silane. The metal vinyl silane may have a formula of MₘR¹ₙR²_{z}, where:
M is a metal;
each R¹ is vinyl silane or a vinyl silane derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal vinyl silanes include, but are not limited to, vinyltrimethylsilane metals, and vinyltrimethoxysilane metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal carboxyl. The metal carboxyl may have a formula of MₘR¹ₙR²_{z}, where:
M is a metal;
each R¹ is carboxyl or a carboxyl derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal carboxyls include, but are not limited to, acetate metals, and 2,2-dimethylpropanato metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal amidinato. The metal amidinato may have a formula of MₘR¹ₙR²_{z}, where:
M is a metal;
each R¹ is amidinato or an amidinato derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal amidinatos include, but are not limited to, N,N′-dimethylamidinato metals, N,N′-diisopropylacetamidinato metals, N,N′-diisopropylformamidinato metals, N,N′-ditertbutylacetamidinato metals, N,N′-disecbutylamidinato metals, N,N′-diisopropylguanidinato metals, and N,N′-diisopropylisopropylamidoguanidinato metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal pyrrolyl derivative. The metal pyrrolyl derivative may have a formula of MₘR¹ₙR²_{z}, where:
M is a metal;
each R¹ is pyrrolyl or a pyrrolyl derivative;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal pyrrolyl derivatives include, but are not limited to, pyrrolyl metals, and 3,5-ditert-butylpyrazolate metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal bidentate. The metal bidentate may have a formula of MₘR¹ₙR²_{z}, where:
M is a metal;
each R¹ is a bidendate group;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal bidendates that may be used include, but are not limited to, diethyldithiocarbamato metals, dimethyldlyoximato metals, 2-methoxyethoxy metals, dimethylaminoethoxy metals, dimethylamino-2-propoxy metals, N,N,2-trimethyl-2butoxy metals, N,N,2-trimethyl-2-propoxy metals, N,N-di-tert-butylbutane-2,3-diamido metals, and 2-amino-pent-2-en-4-onato metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

In certain embodiments, the ligated organometallic precursor is or includes a metal polycyclic ligand. The metal polycyclic ligand may have a formula of MₘR¹ₙR²_{z}, where:
M is a metal;
each R¹ is a polycyclic ligand;
each R² is independently selected from hydrogen, hydroxyl, aliphatic, haloaliphatic, haloheteroaliphatic, heteroaliphatic, aromatic, aliphatic-aromatic, heteroaliphatic-aromatic, or any combination thereof;
m and n are integers that may or may not represent a stoichiometric balance; and
z may be 0 or any positive number.

Example metal polycyclic ligands that may be used include, but are not limited to, 2-(2-amino-prop-2-enyl)-l-pyrrolinyl metals, 1,10-phenanthroline metals, tris(3,5-diethyl-pyrazolyl)borate metals, and 1,2-bis(2,6-di-isopropylphynylimino)acenaphthene metals. Substituted forms of these may also be used, with substitutes including, e.g., hydroxyl, aliphatic, haloaliphatic, haloheteroaliphatic, heteroaliphatic, aromatic, aliphatic-aromatic, heteroaliphatic-aromatic, or any combination thereof.

### C. Non-Metal Sources That React With Metal

In a number of embodiments, the mass source may include a non-metal source that reacts with metal to form a deposited compound. The reaction with metal may produce a metal oxide, metal nitride, metal sulfide, metal carbide, or a combination thereof, which is deposited on the material modified with the functionalization reactant.

The non-metal mass source that reacts with metal may be an oxygen-containing reactant, a nitrogen-containing reactant, a sulfur-containing reactant, a reactive carbon-containing reactant etc.

The non-metal source that reacts with metal may be provided in addition to a mass source for metal. The mass source for metal may provide the metal in neutral form or in ionic form. In cases where the metal is provided in ionic form, the deposition mechanism for depositing the additional material may or may not include reduction of the metal. One or more reactive chemical may be provided to produce the desired additional material (e.g., metal oxide, metal nitride, metal sulfide, etc.). The reactive chemical may be the oxygen-containing reactant, nitrogen-containing reactant, sulfur-containing reactant, etc.

### 3. Additional Species and Additional Baths

In some embodiments, the deposition bath may include one or more additional species. Such species may include, e.g., reducing species, and/or a supporting electrolyte as commonly used for plating. It may be particularly useful to include a reducing species in the deposition bath in cases where the active functional group of the functionalization reactant includes a catalyzing functional group. The catalyzing functional group can catalyze a reaction between the reducing species and a metal to thereby cause reduction (and deposition) of the metal

In certain implementations, the composition of the deposition bath may change over time. For example, in some cases a reducing species may be added to the deposition bath after the substrate has been exposed to the deposition bath for a duration. The reducing species may include one or more reducing functional group as described in relation to the active functional group of the functionalization reactant. Addition of a reducing species may be particularly useful in cases where the functionalization reactant includes a reducing species. After the reducing functional group of the functionalization reactant (which is immobilized on the substrate surface) reacts with and reduces a portion of the metal mass source in the deposition bath, additional reduction/deposition of metal may be encouraged by adding a reducing species to the deposition bath. The reducing species may include the same reducing functional group as the functionalization reactant, or it may include a different reducing functional group.

Alternatively, instead of adding a species to the deposition bath, a second deposition bath may be provided after the substrate is removed from the first deposition bath. The second deposition bath can have a different composition than the first deposition bath. In a particular example, the functionalizing reactant includes a reducing functional group as the active functional group, the first deposition bath includes a metal source such as a metal salt, but is free of reducing species, exposure of the substrate to the first deposition bath results in deposition of a thin layer of metal on the substrate surface, the second deposition bath includes both a reducing species and a metal source such as a metal salt, and exposure of the substrate to the second deposition bath results in further metal deposition. In this example, deposition of metal in the first deposition bath is self-limiting, since further reduction will not occur after the reducing functional groups on the substrate have reacted. By contrast, deposition of metal in the second deposition bath is not self-limiting, because both the reducing species and the metal source are provided freely in the second deposition bath. Similarly, in the case where the reducing species is added to the deposition bath, the metal deposition may occur in a self-limited manner before addition of the reducing species, and in a non-self-limiting manner after addition of the reducing species. In cases where two different deposition baths are used, they may be provided sequentially in a single processing chamber, or the substrate may be moved between different processing chambers.

In some cases, the substrate may be exposed to the functionalization bath and to the deposition bath in a cyclic manner, as discussed further below.

### 4. Control of Process Variables

Various process variables may be controlled during deposition of the additional material on the material modified by the functionalization reactant. Such process variables may be controlled to promote a desired reaction on the substrate and/or to discourage undesired reactions. Examples of process variables that may be controlled include, but are not limited to, temperature of the deposition bath and/or apparatus, degree of aeration of the deposition bath, mass transport within the deposition bath, exposure time of the substrate in the deposition bath, current or voltage applied to the substrate (if any), and composition of the deposition bath (e.g., concentration of dissolved oxygen, concentration and identity of mass source, identity of solvent, presence of additional materials in deposition bath, etc.), etc.

In various examples, the temperature of the deposition bath and/or apparatus may be controlled between about 10-90° C. These temperatures may be controlled with heaters, chillers, heat exchangers, etc. In these of other examples, aeration may be controlled by pumping the solution past a gas exchange membrane and monitoring dissolved gases. In certain embodiments, dissolved O₂ may be controlled to low levels, for example under 0.5 ppm. Mass transport within the bath may be controlled in a number of ways, for example by controlling the flow rate at which the deposition bath passes through the reaction chamber, by controlling the speed at which the substrate rotates (or doesn’t rotate) during deposition, by controlling the rate of a mixing paddle or other mixing element, etc. The exposure duration may be between about 30 seconds to about one hour. Longer exposure times result in greater deposition, with shorter exposure times being more appropriate for deposition of thin layers (e.g., barrier layers, barrier layer precursors, or optional liners), and longer exposure times being more appropriate for deposition of thicker layers (e.g., conductive metal that forms an interconnect).

The composition of the bath may be controlled by regulating the introduction of the solvent, mass source, and any additional species into the deposition bath. In certain cases, the mass source may provide a metal concentration between about 1-1000 mM in the deposition bath. Further, the amount of dissolved oxygen in the deposition bath may be controlled using a degasser and/or a gas injector to achieve a desired oxygen concentration. In certain embodiments, the amount of dissolved oxygen in the deposition bath may be controlled to between about 0-9 ppm, for example about 0.5 ppm or less in some cases, as mentioned above.

### B. Dry Processing: Chemical Vapor Deposition and Atomic Layer Deposition

In certain embodiments, dry processing techniques such as chemical vapor deposition or atomic layer deposition may be used to deposit the additional material on the material modified by the functionalization reactant. In some cases, dry processing techniques may be used to deposit material on a layer that was modified by the functionalization reactant and then further processed using electroless plating of electroplating, as described above. The chemical vapor deposition and atomic layer deposition processes may be driven by thermal energy or plasma energy.

Previously, chemical vapor deposition and atomic layer deposition were not available in the context of BEOI, interconnect formation because of poor nucleation, e.g., on the dielectric material. The functionalization steps described herein significantly improve nucleation behavior, thereby opening the possibility of using chemical vapor deposition and atomic layer deposition to deposit desired materials.

### 1. Mass Source and Deposition Mechanism

Various types of mass sources may be used as described above in relation to the post-functionalization wet processing techniques. Generally, the mass sources described above may be used in connection with dry processing techniques, as desired for a particular application, provided they can be volatilized in the dry reaction chamber.

Likewise, the deposition mechanisms described in relation to the wet processing techniques (e.g., including interactions between the mass source and the functionalization reactant) may apply to the dry processing techniques, as well. Various examples of deposition mechanisms are described throughout the application. The deposition mechanism may involve, e.g., reduction, catalysis, decomplexing, formation of covalent or ionic chemical bonds, bonding through Van der Waals forces, etc.

Generally, chemical vapor deposition involves concurrently exposing the substrate to one or more vapor phase reactants and driving a vapor phase reaction to cause deposition on the substrate. Atomic layer deposition involves cyclically exposing the substrate to one or more reactant (each reactant may be flowed separately), allowing the reactants to adsorb onto the substrate surface (e.g., in a self-limiting process), followed by application of energy to drive a surface reaction that causes deposition on the substrate. With both chemical vapor deposition and atomic layer deposition, the reaction may be driven by thermal energy or plasma energy, as desired for a particular application.

### 2. Control of Process Variables

A number of process variables may be controlled when practicing the dry deposition techniques described herein. Such process variables may be controlled to promote a desired reaction on the substrate and/or to discourage undesired reactions. Example process variables that may be controlled include, but are not limited to, reactant exposure duration and flow rate, purge duration (if any), temperature (e.g., substrate support temperature), pressure, plasma generation conditions (e.g., RF power, RF frequency, duty cycle, substrate bias power, ion energy, etc.). These conditions may be controlled as desired for a particular application.

Generally, reactant exposure durations may be between about 10 seconds to 5 minutes for chemical vapor deposition applications, and between about 1-60 seconds for atomic layer deposition applications. Where purges are used, they may have a duration between about 1-60 seconds. The substrate support may be maintained at a temperature between about 30-400° C. The pressure may be maintained between about 10⁻⁸ Torr (e.g., for ultrahigh vacuum CVD) to 760 Torr (e.g., for atmospheric CVD). The plasma may be generated at an RF power between about 0.2 to 3 kW. The plasma may be generated at one or more frequency, for example 13.56 khz and/or 100 khz. The plasma may have a duty cycle between about 10% and 90%. A bias applied to the substrate support may be between about 0 V to 400 V. While these ranges generally reflect the processing conditions that may be used across many different embodiments, it is understood that in certain cases, any one or more of these processing variables may be controlled within a smaller range.

### III. Cycling Functionalization and Post-Functionalization Processing Steps

Referring again to FIG. 2, the functionalization step in operation 203 modifies an upper surface of the material being functionalized. The deposition step in operation 205 then proceeds to deposit a layer of additional material on the functionalized material. In certain embodiments, operation 203 occurs a single time, and all the additional material deposited in operation 205 may be formed in a single deposition operation. In other embodiments, operations 203 and 205 may cycle with one another. In such cases, second and subsequent iterations of operation 203 may involve functionalizing the material that was deposited in a previous iteration of operation 205 (and, optionally, the material that was modified in the first iteration of operation 203, if any such material remains exposed on the substrate surface at that time). Such cycling can continue until the additional material reaches a desired thickness.

### IV. Barrier Manufacture

A number of embodiments herein involve formation of a barrier layer. With reference to FIG. 1, the barrier layer 105 may be positioned between the dielectric material 103 and the optional liner 107, the seed layer, or the conductive metal 109.

Previously, the type of barrier layer material and the deposition method for forming such barrier layer materials were limited due to the various constraints discussed above. For example, many materials and deposition methods could not be used due to poor nucleation on the dielectric material and poor adhesion between the dielectric material and the material of the barrier layer (or barrier layer precursor).

Advantageously, the techniques described herein enable the manufacture of unique barrier layers and barrier layer stacks. For example, the techniques allow for high quality manufacture of material stacks that were not previously possible to form directly on dielectric material. Further, the techniques allow for manufacture of previously obtainable materials using alternative deposition methods. These factors substantially widen the available processing materials and methods for BEOL interconnect formation.

In some embodiments, the additional material that is deposited on the material modified by the functionalization reactant is the barrier layer or a precursor to the barrier layer. The barrier layer or precursor to the barrier layer may be provided through the wet processes (e.g., electroless plating) or dry processes (e.g., chemical vapor deposition, atomic layer deposition) described herein. Where the additional material is a precursor to the barrier layer, additional processing steps may be taken to convert the precursor to the barrier layer to the actual barrier layer. This additional processing may involve a thermal annealing process and/or a plasma annealing process.

The thermal annealing process may involve exposing the substrate to heat to cause conversion of the barrier layer precursor to the actual barrier layer. In certain embodiments, the anneal process involves exposing the substrate to forming gas (e.g., a mixture of hydrogen and nitrogen), or to another reactive gas. The gas may react with the barrier layer precursor to cause formation of the barrier layer. In certain embodiments, the anneal process may involve exposing the substrate to an elevated temperature between about 150-400° C. In some cases, a substrate support within the chamber used for annealing may be heated to a temperature that falls within this range.

The plasma annealing process may involve exposing the substrate to plasma to cause conversion of the barrier layer precursor to the actual barrier layer. In certain embodiments, the plasma may be a reducing plasma, for example a hydrogen-containing plasma. In other embodiments, this may be an oxidizing plasma, for example an oxygen-containing plasma for the formation of oxide barriers.

### V. Additional Examples

Various examples are described in the context of BEOL interconnect formation. These examples are not intended to be limiting. The examples will be described with reference to FIG. 3. In various examples, the material that is modified with the functionalization reactant in operation 303 is the dielectric material, and the additional material that is deposited on the dielectric material in operation 305 is the barrier layer or a precursor to the barrier layer.

In one example, the functionalization step in operation 303 involves exposing the substrate to a functionalization bath that includes a solvent (e.g., water), which itself reacts with the substrate and creates a uniform set of bond terminations (e.g., hydroxyl groups) on the dielectric material. In this case, water acts as both the solvent and the functionalization reactant of the functionalization bath. With respect to the functionalization reactant, the hydroxyl groups act as both the binding functional group (e.g., a chemisorbing functional group) and the active functional group (e.g., a decomplexing functional group or an adhesive functional group). After operation 303, the substrate is metallized in operation 305 using a vacuum metallization process involving, e.g., chemical vapor deposition or atomic layer deposition. This metallization process deposits a precursor to the barrier layer. In this example, the additional material that is deposited on the material modified by the functionalization reactant is the precursor to the barrier layer. After the precursor to the barrier layer is deposited, it is subjected to a thermal or plasma anneal process, which provides reactive formation of the barrier layer.

In another example, the functionalization step in operation 303 involves exposing the substrate to a functionalization bath that includes a solvent (e.g., water) and a functionalization reactant including a physisorbing group (e.g., catechol) as a binding functional group, and a reducing functional group (e.g., borohydride) as an active functional group. The substrate is exposed to the functionalization bath for a duration, e.g., one minute, which allows the physisorbing group of the functionalization reactant to temporarily bind to the dielectric material on the substrate through Van der Waals forces. The functionalization bath is then flushed away by a solvent (e.g., water) that is free of the functionalization reactant. The substrate is optionally dried. Next, the deposition step in operation 305 involves electroless plating to deposit a precursor to the barrier layer. In this step, the substrate is exposed to a deposition bath, which includes a solvent (e.g., water) and a metal mass source (e.g., a metal sulfate). The metal from the metal mass source interacts with the reducing functional group on the functionalization reactant to cause reduction of the metal mass source and deposition of the metal on the substrate surface. This reduction may be encouraged through the use of thermal control, flow control, or another process modification. After the reaction between the metal and the reducing functional group, further metallization can be performed (e.g., to deposit additional barrier layer precursor) by either repeating the functionalization step in operation 303 and the deposition step in operation 305, or by adding a reducing species (e.g., borohydride) to the deposition bath. As mentioned above, a second deposition bath may also be used (e.g., the second deposition bath including a reducing species) instead of adding the reducing species to the first deposition bath. Where a reducing species is provided in the deposition bath, further reduction of the metal may be catalyzed by the previously reduced metal layer. Alternatively, further metallization may be performed through dry techniques such as chemical vapor deposition or atomic layer deposition. The initial metal layer deposited on the dielectric material in the deposition bath ensures high quality nucleation and adhesion of the metal on the dielectric material. Once the metallization is sufficiently complete (e.g., the precursor to the barrier layer is fully deposited), the substrate is then exposed to a thermal or plasma anneal process to allow reactive formation of the barrier layer from the barrier layer precursor.

In another example, the functionalization step in operation 303 involves exposing the substrate to a functionalization bath that includes a solvent (e.g., toluene) and a functionalization reactant that includes a chemisorbing group (e.g., an alkoxysilane) as the binding functional group and an R group that includes a reducing moiety (e.g., ethylene glycol, a reducing functional group) as the active functional group. The chemisorbing group of the functionalization reactant binds to the dielectric material on the substrate surface. The substrate is processed at a controlled temperature, for example between about 60-80° C., in the presence of a reactant chemical (e.g., water, which may controllably react with the chemisorbing group to silanate the substrate). The functionalization bath is rinsed from the substrate and the substrate is optionally dried. The substrate is then metallized in operation 305 to form a precursor to the barrier layer. In one case the substrate is metallized with a wet process in a deposition bath that includes, e.g., water and a metal salt. The metal salt can be reduced by the reducing functional group of the functionalization reactant. In another case the substrate is metallized with a dry deposition process (e.g., chemical vapor deposition or atomic layer deposition), where the reducing functional group of the functionalization reactant enables/enhances the dry deposition process. After the precursor to the barrier layer is fully metallized, the substrate may be exposed to a thermal or plasma anneal process to thereby convert the barrier layer precursor to the actual barrier layer. In certain embodiments, the anneal process involves heating the substrate to a temperature between about 150-400° C. Alternatively, a plasma anneal process may be performed as described herein.

In another example, the functionalization step in operation 303 involves exposing the substrate to a functionalization bath that includes a solvent (e.g., water) and a functionalization reactant that includes a binding functional group (e.g., a physisorbing functional group such as catechol) and a catalyzing functional group (e.g., cobalt nanoparticles) as an active functional group. The binding functional group binds the functionalization reactant to the dielectric material on the substrate. As a result, the dielectric material is modified to be catalytically active. After the substrate is exposed to the functionalization bath for a duration, the functionalization bath is swept away, the substrate is optionally rinsed and optionally dried, and the substrate is then subjected to electroless plating in operation 305 to form a precursor to the barrier layer. The electroless plating involves exposing the substrate to a deposition bath that includes a solvent (e.g., water), a metal source (e.g., metal sulfate), and a reducing species (e.g., borohydride). The deposition bath may be controlled to regulate temperature, mass transport, dissolved gases, etc. to encourage the reducing species to deposit metal on the catalytically modified dielectric surface. The deposition may continue until the precursor to the barrier layer reaches a desired thickness. After reaching the desired thickness, the substrate may be subjected to a thermal or plasma anneal to encourage the reactive formation of a barrier layer from the barrier layer precursor. In one embodiment the anneal involves heating the substrate to a temperature between about 150-400° C. In another embodiment the anneal involves exposing the substrate to hydrogen plasma.

In another example, the functionalization step in operation 303 involves exposing the substrate to a functionalization bath that includes a solvent (e.g., water) and a functionalization reactant that includes a binding functional group and a decomplexing group (e.g., carboxylic acid) as an active functional group. The binding functional group binds to the dielectric material on the substrate. The substrate is then optionally rinsed and optionally dried. Next, operation 305 involves exposing the substrate to a deposition bath that includes a solvent (e.g., hexane) and a ligated metal precursor (e.g., an acetate-ligated metal). The deposition bath may be controlled to regulate temperature, mass transport, and dissolved gases to encourage deposition of the decomplexed metal onto the substrate surface, thereby forming a barrier layer precursor (or a portion thereof). Deposition of additional barrier layer precursor may be performed by repeating operations 303 and 305. Alternatively or in addition, deposition of additional barrier layer precursor may be performed using a dry technique such as chemical vapor deposition or atomic layer deposition. Where dry techniques are used, they are enabled/enhanced by the previous surface modifications. After the barrier layer precursor is fully deposited, the substrate may be exposed to a thermal or plasma anneal process to convert the barrier layer precursor to the actual barrier layer. In one embodiment the anneal process is a thermal anneal that involves heating the substrate to a temperature between about 150-400° C. In another embodiment the anneal process involves exposing the substrate to hydrogen plasma.

In another example, the functionalization step in operation 303 involves exposing the substrate to a functionalization bath that includes a solvent (e.g., water) that also acts as the functionalization reactant. In this example, hydroxyl groups act as both the binding functional group and the active functional group of the functionalization reactant. The water in the functionalization bath produces hydroxyl terminations on the dielectric material. The substrate is then optionally rinsed and optionally dried. Next, the deposition step in operation 305 involves exposing the substrate to a chemical vapor deposition process involving exposure of the substrate to diethyl zinc, which acts as a metal mass source. The chemical vapor deposition process is enabled/enhanced by the hydroxyl termini on the dielectric material, and results in formation of a layer of zinc on the substrate. The substrate is then subjected to a thermal or plasma anneal process to produce zinc silicate (e.g., in a reaction between silicon-containing dielectric material and the zinc barrier layer precursor material). Excess zinc may then be volatilized by exposing the substrate to hydrogen plasma. Then, a copper seed layer may be deposited (through any available mechanism), followed by electrofill bulk metallization to form the conductive metal of an interconnect structure.

In some embodiments, barrier layers or barrier layer precursors are deposited through chemical vapor deposition or atomic layer deposition processes that are enabled or enhanced by a previous wet functionalization step. In other embodiments, barrier layers or barrier layer precursors are deposited using only wet processes. Such processes may be followed by an anneal to complete formation of the barrier layer, e.g., from a barrier layer precursor.

### VI. Definitions

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl, acetyl, propionyl, isobutyryl, butanoyl, and the like. In some embodiments, the acyl or alkanoyl group is —C(O)—R, in which R is hydrogen, an aliphatic group, or an aromatic group, as defined herein.

By “acyl halide” is meant —C(O)X, where X is a halogen, such as Br, F, I, or Cl.

By “aldehyde” is meant a —C(O)H group.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well.

By “alkyl-aryl,” “alkenyl-aryl,” and “alkynyl-aryl” is meant an aryl group, as defined herein, that is or can be coupled (or attached) to the parent molecular group through an alkyl, alkenyl, or alkynyl group, respectively, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl, alkenyl, alkynyl, and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂-₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is —L—R, in which L is an alkyl group, as defined herein, and R is an aryl group, as defined herein. In some embodiments, the alkenyl-aryl group is —L—R, in which L is an alkenyl group, as defined herein, and R is an aryl group, as defined herein. In some embodiments, the alkynyl-aryl group is —L—R, in which L is an alkynyl group, as defined herein, and R is an aryl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl.

By “alkyl-heteroaryl” is meant a heteroaryl group, as defined herein, attached to the parent molecular group through an alkyl group, as defined herein. In some embodiments, the alkyl-heteroaryl group is —L—R, in which L is an alkyl group, as defined herein, and R is a heteroaryl group, as defined herein.

By “alkyl-heterocyclyl,” “alkenyl-heterocyclyl,” and “alkynyl-heterocyclyl” is meant a heterocyclyl group, as defined herein, that is or can be coupled (or attached) to the parent molecular group through an alkyl, alkenyl, or alkynyl group, respectively, as defined herein. The alkyl-heterocyclyl, alkenyl-heterocyclyl, and/or alkynyl-heterocyclyl group can be substituted or unsubstituted. For example, the alkyl-heterocyclyl, alkenyl-heterocyclyl, and/or alkynyl-heterocyclyl group can be substituted with one or more substitution groups, as described herein for alkyl, alkenyl, alkynyl, and/or heterocyclyl. Exemplary unsubstituted alkyl-heterocyclyl groups are of from 2 to 16 carbons (C₂₋₁₆ alkyl-heterocyclyl), as well as those having an alkyl group with I to 6 carbons and a heterocyclyl group with 1 to 18 carbons (i.e., C₁₋₆ alkyl-C₁₋₁₈ heterocyclyl). Exemplary unsubstituted alkenyl-heterocyclyl groups are of from 3 to 16 carbons (C₃₋₁₆ alkenyl-heterocyclyl), as well as those having an alkenyl group with 2 to 6 carbons and a heterocyclyl group with 1 to 18 carbons (i.e., C₂₋₆ alkenyl-C₁₋₁₈ heterocyclyl). Exemplary unsubstituted alkynyl-heterocyclyl groups are of from 3 to 16 carbons (C₃₋₁₆ alkynyl-heterocyclyl), as well as those having an alkynyl group with 2 to 6 carbons and a heterocyclyl group with 1 to 18 carbons (i.e., C₂₋₆ alkynyl-C₁₋₁₈ heterocyclyl). In some embodiments, the alkyl-heterocyclyl group is —L—R, in which L is an alkyl group, as defined herein, and R is a heterocyclyl group, as defined herein. In some embodiments, the alkenyl-heterocyclyl group is —L—R, in which L is an alkenyl group, as defined herein, and R is a heterocyclyl group, as defined herein. In some embodiments, the alkynyl-heterocyclyl group is —L—R, in which L is an alkynyl group, as defined herein, and R is a heterocyclyl group, as defined herein.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C_{1-18,} C_{1-20,} or C₁₋₂₄ alkoxy groups.

By “alkyl” is meant a saturated monovalent hydrocarbon having at least one carbon atom to 50 carbon atoms (C₁₋₅₀), such as one to 25 carbon atoms (C ₁₋₂₅), or one to ten carbon atoms (C₁₋ ₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (5) aryl; (6) arylalkoxy (e.g., —O—L—R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl, (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkoxy (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., —L—R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., —L—R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₁₋₆ alkyl-C₄₋₁₈ aryl (e.g., —L—R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., —L—R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., —L—R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g., —L—R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋ ₁₂, C₁₋₁₆, C₁₋₁₈, C₁₋₂₀, or C₁₋₁₄ alkyl group.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfonyl” is meant an alkyl group, as defined herein, attached to the parent molecular group through an —SO2— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “amide” is mean —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein.

By “amine” is meant —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein.

By “aminoalkyl” is meant an alkyl group, as defined herein, substituted by an amine group, as defined herein. In some embodiments, the aminoalkyl group is —L—NR¹R², in which L is an alkyl group, as defined herein, and each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein. In other embodiments, the aminoalkyl group is —L—C(NR¹R²)(R³)—R⁴, in which L is a covalent bond or an alkyl group, as defined herein, each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein; and each of R³ and R⁴ is, independently, H or alkyl, as defined herein.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane ir-eiectrons corresponds to the Huckel rule (4n+2). The point of attachment to the parent structure typically is through an aromatic portion of the condensed ring system.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., —L—O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., —L—S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -1-,—SO₂—R, in which each of L and R is, independently, C₁₋₆ alkyl); (9) aryl; (10) amine (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (11) C₁₋₆ amino alkyl (e.g., —L¹—NR¹R² or —L²—C(NR¹R²)(R³)—R⁴, in which L¹ is C₁₋₆ alkyl; L2 is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein; and each of R³ and R⁴ is, independently, H or C₁₋₆ alkyl); (12) heteroaryl; (13) C₁₋₆ alkyl-C₄₋₁₈ aryl (e.g., —L—R, in which L is C₁₋₆ alkyl and R is C₄₋₁₈ aryl); (14) aryloyl (e.g., —C(O)—R, in which R is aryl); (15) azido (e.g., -N₃); (16) cyano (e.g., —CN); (17) C₁₋₆ azidoalkyl (e.g., —L—N₃, in which L is C₁₋₆ alkyl); (18) aldehyde (e.g., —C(O)H); (19) aldehyde-C₁₋₆ alkyl (e.g., —L—C(O)H, in which L is C₁₋₆ alkyl); (20) C₃₋₈ cycloalkyl; (21) C₁₋₆ alkyl-C₃₋₈ cycloalkyl (e.g., —L—R, in which L is C₁₋₆ alkyl and R is C₃₋₈ cycloalkyl); (22) halo; (23) C₁₋₆ haloalkyl (e.g., —L¹—X or —L²—C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, 1-1 or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., —L¹—OH or —L²—C(OH)(R¹)—R², in which L¹ is C₁₋₆ alkyl; L2 is a covalent bond or alkyl; and each of R¹ and R² is, independently, H or C₁₋₆ alkyl, as defined herein); (29) nitro; (30) C₁₋₆ nitroalkyl (e.g., —L¹—NO or —L²—C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C_{I-6} thioalkoxy (e.g., —S—R, in which R is C₁₋₆ alkyl); (35) thio-C₁₋₆ alkoxy-C₁₋₆ alkyl (e.g., -L,—S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., —L—R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₁₋₆ alkyl-C₄₋₁₈ aryl (e.g., —L—R, in which L is C₁₋₆ alkyl and R is C₄₋₁₈ aryl); (38) —(CH₂)ᵣSO₂R¹, where r is an integer of from zero to four and where R^{J} is selected from the group consisting of (a) C₁₋₆ alkyl, (b) C₄₋₁₈ aryl, and (c) C₁₋₆ alkyl-C₄₋₁₈ aryl (e.g., —L—R, in which L is C₁₋₆ alkyl and R is C₄₋₁₈ aryl); (39) —(CH₂)ᵣSO₂NR³ R², where r is an integer of from zero to four and where each of R¹ and R² is, independently, selected from the group consisting of (a) hydrogen, (b) C₁₋₆ alkyl, (c) C₄₋ ₁₈ aryl, and (d) C₁₋₆ alkyl-C₄₋₁₈ aryl (e.g., —L—R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., —L—R, in which L is C₁₋₆ alkyl and R is C₄₋₁₈ aryl), (11) C₃₋₈ cycloalkyl, and (i) C₁₋₆ alkyl-C₃₋₈ cycloalkyl (e.g., —L—R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH)_{:} (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O—L—R, in which L is alkyl and R is cycloalkyl); and (47) arylalkoxy (e.g., —O—L—R, in which L is alkyl and R is aryl). In particular embodiments, an unsubstituted aryl group is a C₄₋₁₈, C₄₋₁₄, C₄₋₁₂, C₄₋ ₁₀, C₆₋₁₈, C₆₋₁₄, C₆₋₁₂, or C₆₋₁₀ aryl group.

By “arylalkoxy” is meant an alkyl-aiyl group, as defined herein, attached to the parent molecular group through an oxygen atom. In some embodiments, the arylalkoxy group is —O—L—R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C-₆₋₁₈ aryloxy group.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is —L—N₃, in which L is an alkyl group, as defined herein. By “azo” is meant an —N═N— group.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant an alkyl-cycloalkyl group, as defined herein, attached to the parent molecular group through an oxygen atom. In some embodiments, the cycloalkylalkoxy group is —O—L—R, in which L is an alkyl group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl, and the like. The cycloalkyl group can also be substituted or unsubstituted. For example, the cycloalkyl group can be substituted with one or more groups including those described herein for alkyl.

By “cycloheteroaliphatic” is meant a heteroaliphatic group, as defined herein, that is cyclic.

By “ester” is meant —C(O)OR or —OC(O)R, where R is selected from aliphatic, heteroaliphatic, haloaliphatic, haloheteroaliphatic, aromatic, as defined herein, or any combination thereof.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is —L—X, in which L is an alkyl group, as defined herein, and X is fluoro, bromo, chloro, or iodo. In other embodiments, the halooalkyl group is —L—C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkyl-aryl,” “heteroalkenyl-aryl,” and “heteroalkynyl-aryl” is meant an aryl group, as defined herein, that is or can be coupled to a compound disclosed herein, where the aryl group is or becomes coupled through a heteroalkyl, heteroalkenyl, or heteroalkynyl group, respectively, as defined herein. In some embodiments, the heteroalkyl-aryl group is —L—R, in which L is a heteroalkyl group, as defined herein, and R is an aryl group, as defined herein. In some embodiments, the heteroalkenyl-aryl group is —L—R, in which L is a heteroalkenyl group, as defined herein, and R is an aryl group, as defined herein. In some embodiments, the heteroalkynyl-aryl group is —L—R, in which L is a heteroalkynyl group, as defined herein, and R is an aryl group, as defined herein.

By “heteroalkyl-heteroaryl,” “heteroalkenyl-heteroaryl,” and “heteroalkynyl-heteroaryl” is meant a heteroaryl group, as defined herein, that is or can be coupled to a compound disclosed herein, where the heteroaryl group is or becomes coupled through a heteroalkyl, heteroalkenyl, or heteroalkynyl group, respectively, as defined herein. In some embodiments, the heteroalkyl-heteroaryl group is —L—R, in which L is a heteroalkyl group, as defined herein, and R is a heteroaryl group, as defined herein. In some embodiments, the heteroalkenyl-heteroaryl group is —L—R, in which L is a heteroalkenyl group, as defined herein, and R is a heteroaryl group, as defined herein. In some embodiments, the heteroalkynyl-heteroaryl group is —L—R, in which L is a heteroalkynyl group, as defined herein, and R is a heteroaryl group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is —L—OH, in which L is an alkyl group, as defined herein. In other embodiments, the hydroxyalkyl group is —L—C(OH)(R¹)—R², in which L is a covalent bond or an alkyl group, as defined herein, and each of R¹ and R² is, independently, H or alkyl, as defined herein.

By “ketone” is meant —C(O)R, where R is selected from aliphatic, heteroaliphatic, aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is —L—NO, in which L is an alkyl group, as defined herein. In other embodiments, the nitroalkyl group is —L—C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S M et al., “Pharmaceutical salts,” J. Pharm. Sci. 1977 January; 66(1): 1-19; and in “Handbook of Pharmaceutical Salts: Properties, Selection, and Use,” Wiley-VCH, April 2011 (2nd rev. ed., eds. P. H. Stahl and C. G. Wermuth, The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amine cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkoxy” is meant an alkyl group, as defined herein, attached to the parent molecular group through a sulfur atom. Exemplary unsubstituted thioalkoxy groups include C₁₋₆ thioalkoxy. In some embodiments, the thioalkoxy group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

### APPARATUS

The methods disclosed herein may be performed by any suitable apparatus or combination of apparatuses. Generally, the functionalization step and wet deposition step described herein may each take place in any wet processing chamber. FIG. 4 provides one example of a wet processing chamber. In a particular embodiment, a single wet processing chamber is used for both the functionalization step and the deposition step.

The wet processing chamber of FIG. 4 includes a vessel 401 for holding the functionalization bath 403 and a substrate holder 405 that supports the substrate 407 as it is wholly or partially immersed in the functionalization bath 403. The substrate holder 405 may move up and down and/or it may rotate the substrate 407 in some cases. Alternatively or in addition, the wet processing chamber may include a nozzle or other fluid distribution device (not shown) for spraying the functionalization bath on the surface of the substrate. The wet processing chamber may include inlets and/or outlets (not shown) for introducing and removing fluid to and from the vessel, respectively. The wet processing chamber may also have a controller (not shown), as discussed below. In cases where the wet processing chamber is used for electroplating, it may further include electrical connections and a power source for connecting to the substrate and to an anode to drive deposition on the substrate (not shown). Example apparatus that may be used include those in the Sabre® product family, available from Lam Research Corporation of Fremont, CA.

In some embodiments, a vapor deposition chamber may be used, for example to perform the deposition step in operation 205 of FIG. 2. The vapor deposition chamber includes a processing chamber capable of processing at low pressure, a substrate support for supporting the substrate during deposition, and inlets and outlets for introducing or removing species to or from the processing chamber. In some cases, the vapor deposition chamber may include a number of stations for simultaneously processing more than one substrate (e.g., one substrate at each station). The vapor deposition chamber may include a controller, as discussed below. The vapor deposition chamber may further include heaters and or chillers for maintaining a desired substrate temperature and/or driving reactions. In cases where the vapor deposition is driven by plasma energy, the vapor deposition chamber may further include a plasma generator. Example vapor deposition apparatuses that may be used include those in the Altus® product family, available from Lam Research Corporation of Fremont, CA.

In various implementations, two or more processing chambers may be included together in a single tool. The tool may include substrate transport mechanisms for moving a substrate between processing chambers. The tool may also include load locks that operate to protect the substrate from exposure to atmosphere, for example during substrate transfer or other operations. In various examples, the tool includes at least (1) a first processing chamber configured to perform one or more wet functionalization operation described above, and (2) a second processing chamber configured to perform deposition of the additional material, as described above. The second processing chamber may be configured for wet processing or dry processing, as desired for a particular application. In one example, both the first and second processing chambers are configured to perform wet processing, with wet functionalization occurring in the first processing chamber and wet deposition of the additional material occurring in the second processing chamber. In another example, only the first processing chamber is configured to perform wet processing (e.g., wet functionalization), and the second processing chamber is configured to perform dry processing (e.g., to dry deposit the additional material). In some other examples, the first and second processing chambers may be provided as separate apparatuses. The apparatuses may be used together to form a system.

As mentioned above, the wet processing chamber and/or the vapor deposition chamber may include a controller. In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of forming an interconnect structure, or a portion thereof, on a substrate, the method comprising:
a. receiving the substrate in a wet processing chamber, the substrate comprising dielectric material with recessed features formed in the dielectric material, wherein the interconnect structure is to be formed in the recessed features, wherein a first material is exposed within the recessed features;
b. contacting the substrate with a functionalization bath comprising a first solvent and a functionalization reactant to form a modified first material on a surface of the first material,
i. wherein the modified first material comprises the first material modified by the functionalization reactant, and
ii. wherein the functionalization reactant comprises (1) a binding functional group that binds the functionalization reactant to the first material, and (2) an active functional group that promotes deposition of a second material on the modified first material, wherein the binding functional group and the active functional group may be the same or different; and
c. depositing the second material on the modified first material,
i. wherein the second material is deposited through electroless plating, electroplating, chemical vapor deposition, or atomic layer deposition, and
ii. wherein one of the following conditions is satisfied:
1. the first material is the dielectric material and the second material is a barrier layer or a barrier layer precursor,
2. the first material is the barrier layer and the second material is a liner,
3. the first material is the barrier layer and the second material is a conductive metal that forms the interconnect of the interconnect structure,
4. the first material is the barrier layer and the second material is a seed layer,
5. the first material is the liner and the second material is the seed layer, or
6. the first material is the liner and the second material is the conductive metal that forms the interconnect of the interconnect structure.

2. The method of claim 1, wherein the active functional group comprises a reducing group comprising a material selected from the group consisting of: a borohydride, a borane, an aldehyde, an acid, a hypophosphite, hydrazine, a glycol, a reductive metal ion, a substituted form of any of these materials, and combinations thereof.

3. The method of claim 1, wherein the active functional group comprises a catalyzing functional group.

4. The method of claim 3, wherein the catalyzing functional group comprises at least one of nanoparticles of a metal or nanoparticles of a metal oxide.

5. The method of claim 1, wherein the active functional group comprises a decomplexing functional group.

6. The method of claim 5, wherein the decomplexing functional group comprises a material selected from the group consisting of: a hydroxide, an alcohol, an ester, an ether, a carboxylic acid, and combinations thereof.

7. The method of claim 1, wherein the active functional group comprises an adhesive functional group.

8. The method of claim 7, wherein the adhesive functional group comprises a material selected from the group consisting of: a hydroxide, an alcohol, a carboxylic acid, a metal oxide, and combinations thereof.

9. The method of claim 1, wherein the binding functional group comprises a physisorbing functional group.

10. The method of claim 9, wherein the physisorbing functional group comprises a material selected from the group consisting of: a phosphonate, a carboxylate, an amine, an alkyne, an alkene, catechol, a catechol derivative, and combinations thereof.

11. The method of claim 1, wherein the binding functional group comprises a chemisorbing functional group.

12. The method of claim 11, wherein the chemisorbing functional group comprises a material selected from the group consisting of: a hydroxide, a silane, an ester, a silazane, a silyl-acetamide, a silyl-imidazole, and combinations thereof.

13. The method of claim 1, wherein the functionalization bath further comprises a pH adjustment species comprising a base or an acid.

14. The method of claim 13, wherein the base or acid of the pH adjustment species comprises a material selected form the group consisting of: triethylamine, tetramethylammonium hydroxide, ammonium hydroxide, sulfuric acid, hydrochloric acid, nitric acid, phosphoric acid, and combinations thereof.

15. The method of claim 1, wherein the second material is deposited through electroless plating or electroplating, and wherein the second material is deposited in a deposition bath comprising a solvent and a metal mass source, wherein the second material comprises a metal in the metal mass source.

16. The method of claim 1, wherein the second material is deposited through chemical vapor deposition or atomic layer deposition, and wherein the second material is deposited in a vapor deposition chamber using a metal mass source, wherein the second material comprises a metal in the metal mass source.

17. The method of claim 1, wherein the second material is deposited through electroless plating, electroplating, chemical vapor deposition, or atomic vapor deposition, wherein the second material is deposited using a metal mass source, wherein the second material comprises a metal in the metal mass source, and wherein the metal mass source comprises a metal salt.

18. The method of claim 17, wherein the metal salt comprises a material selected from the group consisting of: a metal halide, a metal sulfite, a metal sulfate, a metal hydroxide, a metal nitrate, a metal phosphite, a metal phosphate, and combinations thereof.

19-54. (canceled)

55. A system for forming an interconnect structure, or a portion thereof, on a substrate, the system comprising:
a. a first wet processing chamber;
b. an optional second wet processing chamber;
c. an optional vacuum chamber; and
d. a controller configured to cause any of the methods described herein.

56. A system for forming an interconnect structure, or a portion thereof, on a substrate, the system comprising:
a. a first wet processing chamber;
b. an optional second wet processing chamber;
c. an optional vacuum chamber; and
d. a controller configured to cause:
i. receiving the substrate in the wet processing chamber, the substrate comprising dielectric material with recessed features formed in the dielectric material, wherein the interconnect structure is to be formed in the recessed features, wherein a first material is exposed within the recessed features;
ii. contacting the substrate with a functionalization bath comprising a first solvent and a functionalization reactant to form a modified first material on a surface of the first material,
1. wherein the modified first material comprises the first material modified by the functionalization reactant, and
2. wherein the functionalization reactant comprises (A) a binding functional group that binds the functionalization reactant to the first material, and (B) an active functional group that promotes deposition of a second material on the modified first material, wherein the binding functional group and the active functional group may be the same or different; and
iii. depositing the second material on the modified first material while the substrate is either in the first wet processing chamber, the optional second wet processing chamber, or the optional vacuum chamber,
1. wherein the second material is deposited through electroless plating, electroplating, chemical vapor deposition, or atomic layer deposition, and
2. wherein one of the following conditions is satisfied:
a. the first material is the dielectric material and the second material is a barrier layer or a barrier layer precursor,
b. the first material is the barrier layer and the second material is a liner,
c. the first material is the barrier layer and the second material is a conductive metal that forms the interconnect of the interconnect structure,
d. the first material is the barrier layer and the second material is a seed layer,
e. the first material is the liner and the second material is the seed layer, or
f. the first material is the liner and the second material is the conductive metal that forms the interconnect of the interconnect structure.
